(19) United States
(12) Patent Application Publication
(10) Pub. No.: US 2020/0371437 A1
(43) Pub. Date: Nov. 26, 2020

(54) METHOD FOR PRODUCING A PLANAR POLYMER STACK

(71) Applicant: ARKEMA FRANCE, Colombes (FR)

(72) Inventors: Xavier CHEVALIER, Grenoble (FR); Ilias ILIOPOULOS, Paris (FR)

(21) Appl. No.: 16/766,490

(22) PCT Filed: Nov. 23, 2018
(86) PCT No.: PCT/FR2018/052962

§ 371 Date: May 22, 2020

(30) Foreign Application Priority Data
Nov. 24, 2017 (FR) 1761179

(51) Int. Cl. G03F 7/095; G03F 7/00; G03F 7/20; G03F 7/42; G03F 1/78

(52) U.S. Cl. CPC G03F 7/0955; G03F 7/0002; G03F 1/78; G03F 7/427; G03F 7/2059

(57) ABSTRACT

The invention relates to a method for manufacturing a flat polymeric stack, said stack comprising one or more first and one second layer of (co)polymer (20, 30) stacked one on the other, the first underlying (co)polymer layer (20) not having undergone any prior treatment allowing its crosslinking, at least one of the (co)polymer layers initially being in a liquid or viscous state, said method being characterized in that the upper layer (30), known as the top coat (TC), is deposited on the first layer (20) in the form of a prepolymer composition (pre-TC), comprising one or more monomer(s) and/or dimer(s) and/or oligomer(s) and/or polymer(s) in solution, and in that it is then subjected to a stimulus capable of causing a crosslinking reaction of the molecular chains within said layer (30, TC).

### FIELD OF THE INVENTION

The present invention relates to the field of polymeric stacks.

More particularly, the invention relates to a method for controlling the planarity of such stacks. The invention further relates to a method for manufacturing a nanolithography mask using such a stack, the planarity of which is controlled, and a polymeric stack obtained via said planarity control method.

Polymer stacks are used in a multitude of industrial applications, among which mention may be made, in a non-exhaustive manner, of the production of coatings for the aerospace or aeronautical or motor vehicle or wind turbine sector, inks, paints, membranes, biocompatible implants, packaging materials, or optical components, for instance optical filters, or microelectronic, optoelectronic, or microfluidic components. The invention applies to all the applications, whatever they are, provided that the stack comprises at least two polymer materials stacked one on the other.

Among the various possible industrial applications, the invention also concerns, in a non-exhaustive manner, applications dedicated to the organic electronic field, and more particularly to directed self-assembly, also called DSA (from the English acronym “Directed Self-Assembly”) nanolithography applications, for which other requirements need to be concomitantly met.

### PRIOR ART

The stability and behavior of polymer thin films on a solid substrate or on an underlying layer, which is itself solid or liquid, are technologically important in some industrial applications, for instance the protection of surfaces for the aerospace or aeronautical or motor vehicle or wind turbine sector, paints, inks, the manufacture of membranes, or alternatively microelectronic, optoelectronic, or microfluidic components.

Polymer-based materials have interfaces which are said to be of a low surface energy, where the molecular chains thus have a relatively low cohesion energy, by comparison with other solid interfaces such as the surfaces of metals or oxides with a markedly higher surface energy, which are thus less susceptible to deformation under the effect of any force.

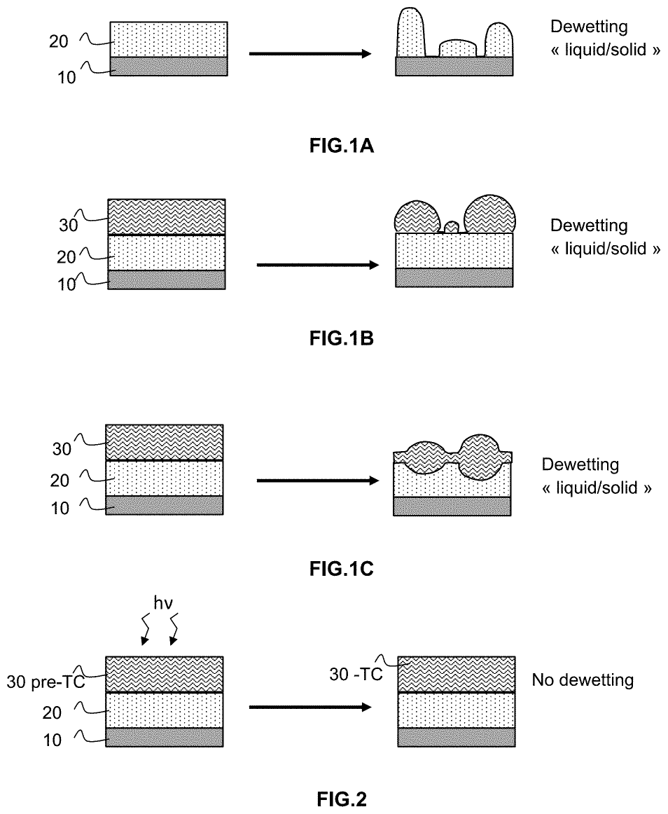

In particular, the dewetting phenomenon of a polymer film deposited in the liquid or viscous state onto the surface of an underlying layer, which is itself in the solid or liquid state, has been known for a long time. By “liquid or viscous polymer” is meant a polymer which has, at a temperature above the glass transition temperature, as a result of its rubbery state, an increased capacity for deformation due to the possibility given to its molecular chains to move freely. Hydrodynamic phenomena which are the cause of dewetting appear as long as the material is not in a solid state, i.e. non-deformable due to the negligible mobility of its molecular chains. This dewetting phenomenon is characterized by the spontaneous removal of the polymer film applied to the surface of the underlying layer when the initial stack system is left to evolve freely over time. Loss of continuity of the initial film and a variation in thickness then arise. The film does not spread and forms one or more caps/spherical droplets, giving rise to a non-zero contact angle with the underlying surface. This phenomenon is illustrated in FIGS. 1A to 1C. FIG. 1A more particularly shows a solid substrate 10 onto which is deposited a layer of polymer 20 in the liquid or viscous state. In this first case, the stack system is in a “liquid/solid” configuration. After the deposition of such a polymer layer 20, the dewetting phenomenon occurs and the polymer 20 no longer spreads properly on the surface of the substrate 10, forming spherical caps and resulting in a stack, the surface of which is not flat. FIG. 1B shows a solid substrate 10, onto which is deposited a first layer of polymer 20, this first layer being solidified at the time of the deposition of a second upper layer of polymer 30. In this case, the second layer of polymer 30 on the upper surface is deposited in a liquid or viscous state onto the solid surface of the first layer of polymer 20. It is said that the interface between the two layers of polymer is in a “liquid/solid” configuration. In this case too, after a certain time, a dewetting phenomenon occurs and the polymer 30 does not spread properly on the surface of the first polymer layer 20, forming spherical caps and resulting in a stack, the surface of which is not flat. Finally, FIG. 1C shows a solid substrate 10, onto which is deposited a first layer of polymer 20 in the liquid or viscous state, which is itself covered with a second upper layer of polymer 30 in the liquid or viscous state. In this case, the interface between the two layers of polymer is in a “liquid/liquid” configuration. In this case too, the second upper layer 30 of polymer does not spread properly on the surface of the first polymer layer 20 and it may also, optionally, become partly solubilized in the first polymer layer 20, resulting in an inter-diffusion phenomenon at the interface between the two layers. This layer 30 then deforms, among other things under the combined effect of gravity, of its own density, of its surface energy, of the viscosity ratio between the materials of the polymer layers 30 and 20 that are present, and also under the effect of the Van der Waals interactions leading to the amplification of the capillary waves of the system. This deformation leads to the production of a discontinuous film 30, also including spherical caps, and also deforming the first underlying polymer layer 20. The result is a stack, the surface of which is not flat and the interface between the two layers of polymer of which is not clear.

The coefficient of spreading of a liquid or viscous layer, denoted S, is given by Young's equation below:

S=γ_{C}−(γ_{CL}+γ_{L}),

in which γ_{C} represents the surface energy of the solid or liquid underlying layer, γ_{L} represents the surface energy of the upper layer of a liquid polymer, and γ_{CL} represents the energy at the interface between the two layers. By surface energy (denoted γₓ) of a given material “x” is meant the excess energy at the surface of the material in comparison with that of the material within its bulk. When the material is in the liquid form, its surface energy is equivalent to its surface tension. When the coefficient of spreading S is positive, then the wetting is total and the liquid film spreads completely over the surface of the underlying layer. When the coefficient of spreading S is negative, then the wetting is partial, i.e. the film does not spread completely on the surface of the underlying layer and a dewetting phenomenon takes place if the initial stack system is left to evolve freely.

In these systems of stacks of layer(s) of polymer materials, in which the configurations may be, for example, “liquid/solid” or “liquid/liquid”, the surface energies of the various layers may be very different, thus making the entire system metastable or even unstable due to the mathematical formulation of the spreading parameter S.

When a stack system, deposited on any substrate, comprises different layers of polymer material in the liquid/viscous state, stacked on top of each other, the stability of the entire system is governed by the stability of each layer at the interface with different materials.

For this type of metastable, or even unstable, liquid/liquid system, dewetting phenomena have been observed during the relaxation of the initial constraints, this being independent of the nature of the materials involved (small molecules, oligomers, polymers). Various studies (F. Brochart-Wyart et al., Langmuir, 1993, 9, 3682-3690; C. Wang et al., Langmuir, 2001, 17, 6269-6274; M. Geoghegan et al., Prog. Polym. Sci., 2003, 28, 261-302) have demonstrated and explained theoretically and experimentally the behavior and also the origin of the dewetting observed. Irrespective of the mechanisms (spinodal decomposition or nucleation/growth), this type of liquid/liquid system has a tendency to be particularly unstable and leads to the introduction of severe defects in the form of a discontinuity of the film under consideration, i.e. in the example of FIG. 1C the first polymer layer 20, the initial planarity of which is thereby disrupted, with the appearance, in the best of cases, of holes in the film or the double-layer of polymer films, thus making it unusable for the intended applications.

Dewetting is a thermodynamically favorable phenomenon, the materials spontaneously seeking to minimize the surface of contact with each other. However, for all the applications intended above, it is specifically sought to avoid such a phenomenon, in order to have perfectly flat surfaces. It is also sought to avoid inter-diffusion phenomena between the layers so as to obtain clear interfaces.

A first problem that the Applicant sought to solve thus consists in avoiding the appearance of dewetting phenomena in polymer stack systems, in which at least one of the polymers is in a liquid/viscous state, and this irrespective of the polymers of the system and irrespective of the intended applications.

A second problem that the Applicant sought to solve consists in avoiding inter-diffusion phenomena at the interfaces, so as to obtain clear interfaces.

In the particular context of applications in the field of directed self-assembly, or DSA, nanolithography, block copolymers, which are capable of nano-structuring at an assembly temperature, are used as nanolithography masks. To do this, systems of stacks of liquid/viscous materials are also used. These stacks comprise a solid substrate, onto which is deposited at least one film of block copolymer, subsequently denoted BCP. This block copolymer BCP film, intended to form a nanolithography mask, is necessarily in a liquid/viscous state at the assembly temperature, so that it can self-organize in nanodomains, due to a phase segregation between the blocks. The block copolymer film thus deposited on the surface of the substrate is thus subject to dewetting phenomena when it is brought to its assembly temperature.

Furthermore, for the intended application, such a block copolymer must also preferably have nanodomains oriented perpendicular to the lower and upper interfaces of the block copolymer, so as to be able thereafter to selectively remove one of the blocks of the block copolymer, to create a porous film with the residual block(s) and to transfer, by etching, the patterns thus created onto the underlying substrate.

However, this condition of perpendicularity of the patterns is met only if each of the lower (substrate/block copolymer) and upper (block copolymer/ambient atmosphere) interfaces is “neutral” with respect to each of the blocks of said copolymer BCP, i.e. if there is no predominant affinity of the interface under consideration for at least one of the blocks constituting the block copolymer BCP.

In this perspective, the possibilities for controlling the affinity of the “lower” interface, located between the substrate and the block copolymer, are nowadays well known, and controlled. Two main techniques exist for controlling and guiding the orientation of the blocks of a block copolymer on a substrate: graphoepitaxy and chemical epitaxy. Graphoepitaxy uses a topological constraint to force the block copolymer to organize in a predefined space commensurable with the periodicity of the block copolymer. For this, graphoepitaxy consists in forming primary patterns, known as guides, on the surface of the substrate. These guides, of any chemical affinity with regard to the blocks of the block copolymer, delimit areas within which a layer of block copolymer is deposited. The guides make it possible to control the organization of the blocks of the block copolymer to form secondary patterns of a higher resolution, inside these areas. Conventionally, the guides are formed by photolithography. By way of example, among the possible solutions, if the intrinsic chemistry of the monomers constituting the block copolymer allow it, a statistical copolymer having an astutely selected ratio of the same monomers as those of the block copolymer BCP can be grafted onto the substrate, thus making it possible to balance the initial affinity of the substrate for the block copolymer BCP. This is, for example, the conventional method of choice used for a system comprising a block copolymer such as PS-b-PMMA and described in the article by Mansky et al., Science, 1997, 275, 1458. Regarding chemical epitaxy, it uses a contrast in chemical affinities between a pattern predrawn on the substrate and the different blocks of the block copolymer. Thus, a pattern having a high affinity for only one of the blocks of the block copolymer is predrawn on the surface of the underlying substrate, in order to allow the perpendicular orientation of the blocks of the block copolymer, while the remainder of the surface shows no particular affinity for the blocks of the block copolymer. To do this, a layer comprising, on the one hand, neutral areas (consisting, for example, in a grafted statistical copolymer), with no particular affinity for the blocks of the block copolymer to be deposited and, on the other hand, areas with an affinity (consisting, for example, of a homopolymer grafted with one of the blocks of the block copolymer to be deposited and serving as an anchoring point for this block of the block copolymer) is deposited on the surface of the substrate. The homopolymer serving as an anchoring point can be produced with a width slightly greater than that of the block with which it has a preferential affinity and allows, in this case, a “pseudo-equitable” distribution of the blocks of the block copolymer on the surface of the substrate. Such a layer is said to be “pseudo-neutral” as it allows an equitable or “pseudo-equitable” distribution of the blocks of the block copolymer on the surface of the substrate, with the result that the layer does not have, in its overall nature, any preferential affinity for one of the blocks of the block copolymer. Consequently, such a chemically epitaxied layer on the surface of the substrate is considered as being neutral with regard to the block copolymer.

On the other hand, the control of the so-called “upper” interface of the system, i.e. the interface between the block copolymer and the surrounding atmosphere, remains markedly less well controlled at the present time. Among the various approaches described in the prior art, a first promising solution, described by Bates et al. in the publication entitled “Polarity-switching top coats enable orientation of sub-10 nm block copolymer domains”, Science 2012, Vol. 338, pages 775-779, and in document US 2013/280497, consists in controlling the surface energy at the upper interface of a block copolymer to be nanostructured, of the poly(trimethylsilylstyrene-b-lactide), denoted PTMSS-b-PLA, type, or the poly(styrene-b-trimethylsilylstyrene-b-styrene), denoted PS-b-PTMSS-b-PS, type, by introducing an upper layer, also referred to as a “top coat” and subsequently denoted TC, deposited on the surface of the block copolymer. In this document, the top coat, which is polar, is deposited by spin coating (or “spin coating” in Anglo-Saxon terminology) on the block copolymer film to be nanostructured. The top coat is soluble in an acidic or basic aqueous solution, which allows it to be applied onto the upper surface of the block copolymer, which is insoluble in water. In the example described, the top coat is soluble in an aqueous ammonium hydroxide solution. The top coat is a statistical or alternating copolymer, the composition of which comprises maleic anhydride. In solution, the opening of the maleic anhydride ring allows the top coat to lose ammonia. During the self-organization of the block copolymer at the annealing temperature, the maleic anhydride ring of the top coat closes, the top coat undergoes a transformation into a less polar state and becomes neutral with respect to the block copolymer, thereby allowing a perpendicular orientation of the nanodomains with respect to the two lower and upper interfaces. The top coat is then removed by washing in an acidic or basic solution.

In such systems, based on stacks denoted TC/BCP/substrate, the top coat TC, applied by spin coating, is a liquid/viscous state. The block copolymer BCP is also necessarily in its liquid/viscous state, so as to be able to self-organize at the assembly temperature and create the desired patterns. Now, in the same manner as for any polymeric stack, the application of such a top coat TC layer, in the liquid or viscous state, onto a layer of block copolymer BCP which is itself in the liquid or viscous state, leads to the appearance, at the block copolymer/top coat (BCP/TC) upper interface, of the same dewetting phenomenon as that described above with regard to FIG. 1C. Indeed, on account of hydrodynamic phenomena leading to the amplification of capillary waves of the top coat TC layer and of its interaction with the underlying layer of block copolymer BCP, this type of stack has a tendency to be particularly unstable and leads to the introduction of severe defects in the form of a discontinuity in the block copolymer BCP film, thus making it unsuitable for use, for example, as a nanolithography mask for electronics. Moreover, the thinner the deposited polymer film, that is to say at least once the gyration radius of a molecular chain of the polymer under consideration, the more unstable or metastable it will tend to be, especially when the surface energy of the underlying layer is different from that of said polymer and the system is left to evolve freely. Finally, the instability of the polymer film deposited on the underlying layer is generally all the more important as the “annealing temperature/annealing time” couple is high.

Regarding the first solution described by Bates et al., just after the step of depositing the top coat TC layer by spin coating, solvent remains trapped in the polymer chains, along with a less rigid “open maleate” form of the monomer. These two parameters imply, de facto, a plasticization of the material and thus a significant decrease in the glass transition temperature (Tg) of the material before thermal annealing allowing the return of said material to the anhydride form. Furthermore, the difference between the assembly temperature of the block copolymer BCP (which is 210° C. for the PS-b-PTMSS-b-PS block copolymer and 170° C. for the PTMSS-b-PLA block copolymer) relative to the glass transition temperature of the top coat TC layer (which is 214° C. for the TC-PS top coat deposited on the PS-b-PTMSS-b-PS block copolymer and 180° C. for the TC-PLA top coat deposited on the PTMSS-b-PLA block copolymer, respectively) is too small to be able to ensure the absence of a dewetting phenomenon. Finally, the assembly temperature does not make it possible either to ensure correct assembly kinetics for the formation of the patterns in the context of the intended DSA application.

Furthermore, still regarding the solution described by Bates et al., to avoid the problem of inter-diffusion or solubilization of the top coat TC layer in the underlying block copolymer BCP, the glass transition temperature Tg of the top coat TC layer must be high and greater than the assembly temperature of the block copolymer. To achieve this, the constituent molecules of the top coat TC layer are selected so as to have a high molecular mass.

The constituent molecules of the top coat TC must thus have a high glass transition temperature Tg, and also long molecular chains, so as to limit the solubilization of the top coat TC layer in the underlying block copolymer BCP and avoid the appearance of a dewetting phenomenon. These two parameters are particularly constraining in terms of synthesis. Indeed, the top coat TC layer must have a sufficient degree of polymerization so that its glass transition temperature Tg is much higher than the assembly temperature of the underlying block copolymer. Furthermore, the possible choice of the comonomers, for varying the intrinsic surface energy of the top coat TC layer so that the latter has a neutral surface energy with respect to the underlying block copolymer, is limited. Finally, in their publication, Bates et al. describe the introduction of comonomers to rigidify the chains. These added comonomers are rather carbon-based monomers, of the norbornene type, which do not promote a correct solubilization in polar/protic solvents.

On the other hand, for the correct functioning of such stacked polymer systems intended for applications in the field of directed self-assembly nanolithography, not only must dewetting and inter-diffusion phenomena be avoided so as to meet the conditions of surface planarity and clear interface, but, in addition, additional requirements must be met in order especially to allow the production of a perfect perpendicularity of the nanodomains of the block copolymer after assembly.

Among these additional requirements to be met, the top coat TC layer must be soluble in a solvent, or solvent system, in which the block copolymer BCP itself is insoluble, otherwise the block copolymer will redissolve at the time of the deposition of the top coat layer, the deposition of such a layer generally being performed by the well-known spin coating technique. Such a solvent is also known as a “block copolymer orthogonal solvent”. It is also necessary for the top coat layer to be able to be easily removed, for example by rinsing in an appropriate solvent, which is itself preferably compatible with the standard electronics equipment. In the publication by Bates et al. mentioned above, the authors circumvent this point by using, as the main base of the polymer chain constituting the top coat TC, a monomer (maleic anhydride), the polarity of which changes once it is in basic aqueous solution (with the introduction of charges into the chain by acid-base reaction), and then returns to its initial uncharged form once the material has been deposited and then annealed at high temperature.

A second requirement is the fact that the top coat TC layer must preferably be neutral with respect to the blocks of the block copolymer BCP, i.e. it must have an equivalent interfacial tension for each of the various blocks of the block copolymer to be nanostructured, at the time of the heat treatment allowing structuring of the block copolymer BCP, so as to ensure the perpendicularity of the patterns relative to the interfaces of the block copolymer film.

In view of all the above-mentioned difficulties, the chemical synthesis of the top coat material may prove to be a challenge in itself. Despite the difficulties in synthesizing such a top coat layer and the dewetting and inter-diffusion phenomena to be avoided, the use of such a layer appears as being essential for orienting the nanodomains of a block copolymer perpendicular to the interfaces.

In a second solution described in the document from J. Zhang et al., Nano Lett., 2016, 16, 728-735, and also in documents WO 16/193581 and WO 16/193582, a second block copolymer, BCP No. 2, is used as top coat layer, “embedded” with the first block copolymer BCP in solution. The block copolymer BCP No. 2 comprises a block of a different solubility, for example a fluorinated block, and also of a low surface energy, thus naturally allowing segregation of the second block copolymer BCP No. 2 at the surface of the first block copolymer and rinsing in a suitable solvent, for example a fluorinated solvent, once the assembling is complete. At least one of the blocks of the second block copolymer has, at the organization temperature, a neutral surface energy with respect to all of the blocks of the first block copolymer film to be organized perpendicularly. Just like the first solution, this solution also favors the appearance of dewetting phenomena.

In a third solution, described by H. S. Suh et al., Nature Nanotech., 2017, 12, 575-581, the authors deposit the top coat TC layer by the iCVD (from the English acronym “initiated Chemical Vapour Deposition”) method, which allows them to overcome the problem of the top coat TC solvent at the time of the deposition, which must be “orthogonal” to the block copolymer BCP, i.e. it must be a non-solvent for the block copolymer BCP. However, in this case, the surfaces to be covered require special equipment (an iCVD chamber) and thus involve a longer processing time than with a simple deposition by spin coating. Furthermore, the ratios of various monomers to be reacted may vary from one iCVD chamber to another, to the point that it appears necessary to make constant adjustments/corrections and perform quality control tests, in order to be able to use such a method in the electronics field.

The various solutions described above for making a stack of polymer layers with a flat surface, with clear interfaces between the layers, are not entirely satisfactory. In addition, when such a stack is intended for DSA applications, and comprises a block copolymer film to be nanostructured with nanodomains which must be oriented perfectly perpendicular to the interfaces, the existing solutions generally remain too tedious and complex to implement and do not make it possible to significantly reduce the defectivity associated with dewetting and with the imperfect perpendicularity of the patterns of the block copolymer. The envisaged solutions also appear too complex to be able to be compatible with industrial applications.

Consequently, in the context of using stacks comprising block copolymers BCP in the form of thin films, intended to be used as nanolithography masks, for applications in organic electronics, it is imperative to be able to ascertain not only that the block copolymer BCP film entirely covers the pre-neutralized surface of the substrate under consideration without dewetting thereof, and that the top coat layer entirely covers the surface of the block copolymer without dewetting, but also that the top coat layer deposited at the upper interface does not have predominant affinity for any of the blocks of the block copolymer, so as to ensure the perpendicularity of the patterns with respect to the interfaces.

### Technical Problem

The aim of the invention is thus to overcome at least one of the drawbacks of the prior art. The invention is especially directed towards proposing a method for controlling the planarity of a polymer stack system, said method making it possible to avoid the appearance of dewetting phenomena of the stacked polymer layers, while at least one of the lower layers of the stack retains the possibility of being in a liquid-viscous state depending on the temperature, and also of solubilization phenomena between the various layers and inter-diffusion at the interfaces, so as to obtain stacks, the layers of which are perfectly flat and for which the interfaces between two layers are clear. The method must also be simple to perform and allow industrial implementation.

The invention is also directed towards overcoming other problems specific to applications dedicated to directed self-assembly (DSA) nanolithography. In particular, it is directed towards allowing the deposition of a top coat layer on the surface of a block copolymer, which avoids the appearance of the above-mentioned dewetting and inter-diffusion phenomena and which also has a neutral surface energy with respect to the blocks of the underlying block copolymer, so that the nanodomains of the block copolymer can become oriented perpendicular to the interfaces, at the assembly temperature of said block copolymer. It is also directed towards allowing the deposition of such a top coat layer with a solvent which is orthogonal to the underlying block copolymer, i.e. which is not liable to attack, solvate even partially or dissolve said underlying block copolymer.

### BRIEF DESCRIPTION OF THE INVENTION

To this end, the invention relates to a method for manufacturing a flat polymeric stack, said method consisting in depositing on a substrate (10) a first layer (20) of non-crosslinked (co)polymer, and then a second layer (30) of (co)polymer, at least one of the (co)polymer layers initially being in a liquid or viscous state, said method being characterized in that, at the time of the deposition of the upper layer on the first layer, the upper layer is in the form of a prepolymer composition, comprising one or more monomer(s) and/or dimer(s) and/or oligomer(s) and/or polymer(s) in solution, and in that an additional step consists in submitting said upper layer to a stimulus, selected from plasma, ion bombardment, electrochemical process, chemical species, light radiation, capable of causing a crosslinking reaction of the molecular chains within said prepolymer layer and allowing the production of a crosslinked so-called top coat layer.

Thus, the top coat layer rapidly crosslinks to form a rigid network, to the point that it has neither the time to dewet nor the physical possibility of dewetting. The upper layer thus crosslinked makes it possible to solve several different technical problems presented previously. Firstly, this crosslinking makes it possible to eliminate the dewetting inherent in the top coat layer, since the molecular movements of the top coat layer are very restricted once it has been entirely crosslinked. Secondly, this crosslinking of the upper layer also makes it possible to eliminate the typical possibilities of “liquid-liquid” dewetting of the system, where the top coat layer can be considered as a potentially deformable solid, rather than as a viscous fluid after crosslinking and once the system has been brought to a working temperature, above the glass transition temperature of the underlying polymer layer 20. Thirdly, the crosslinked top coat layer also makes it possible to stabilize the underlying polymer layer so that it does not dewet its substrate. Another noteworthy and non-negligible point is that the step of chemical synthesis of the material of the top coat layer is facilitated since it makes it possible to overcome the problems associated with the need to synthesize a material of a high molecular mass, thus offering better control over the final architecture of the material (composition, mass, etc.) and also synthetic operating conditions that are markedly less drastic (acceptable content of impurities, solvent, etc.) than in the case of materials of high molecular masses. Finally, the use of small molecular masses for the upper layer makes it possible to broaden the range of possible orthogonal solvents for this material. Indeed, it is well known that polymers of small masses are easier to solubilize than polymers of the same chemical composition which have large masses.

According to other optional characteristics of the method:
the stimulus applied to initiate the crosslinking reaction is an electrochemical process applied via an electron beam;
the stimulus for causing the crosslinking reaction within the prepolymer layer is a light radiation in wavelength ranges from ultraviolet to infrared, between 10 nm and 1500 nm and preferably between 100 nm and 500 nm;
the step of photo-crosslinking the layer of prepolymer composition is performed at an energy dose of less than or equal to 200 mJ/cm², preferably less than or equal to 100 mJ/cm², and more preferably less than or equal to 50 mJ/cm²;
the crosslinking reaction propagates within the upper layer, by bringing the stack to a temperature below 150° C. and preferably below 110° C., for a time of less than 5 minutes, and preferably less than 2 minutes;
the prepolymer composition is a composition formulated in a solvent, or used without a solvent, and which comprises at least: one monomer, dimer, oligomer, or polymer chemical entity, or any mixture of these various entities, of totally or partly identical chemical nature, and each including at least one chemical function capable of ensuring the crosslinking reaction under the effect of a stimulus; and one or more chemical entities capable of initiating the crosslinking reaction under the effect of the stimulus, such as a radical generator, an acid, and/or a base;
at least one of the chemical entities of the prepolymer composition has at least one fluorine and/or silicon and/or germanium atom, and/or one aliphatic carbon-based chain of at least two carbon atoms in its chemical formula;
said prepolymer composition also comprises in its formulation: a chemical entity selected from an antioxidant, a weak acid or base, which is capable of trapping said chemical entity capable of initiating the crosslinking reaction, and/or one or more additives for improving the wetting and/or the adhesion, and/or the uniformity of the upper top coat layer deposited on the underlying layer, and/or one or more additives for absorbing one or more ranges of light radiations of different wavelengths, or for modifying the electrical conductivity properties of the prepolymer;
the prepolymer composition comprises a crosslinking photoinitiator and it is crosslinked by radical polymerization;
when the polymerization is radical-mediated, the constituent monomer(s) and/or dimer(s) and/or oligomer(s) and/or polymer(s) of the prepolymer layer are selected from the non-exhaustive list of acrylate or diacrylate or triacrylate or multi-acrylate, methacrylate, or multi-methacrylate, or polyglycidyl or vinyl, fluoroacrylate or fluoromethacrylate, vinyl fluoride or fluorostyrene, alkyl acrylate or methacrylate, hydroxyalkyl acrylate or methacrylate, alkylsilyl acrylate or methacrylate derivatives, unsaturated esters/acids such as fumaric or maleic acids, vinyl carbamates and carbonates, allyl ethers, and thiol-ene systems;
when the polymerization is radical-mediated, the photoinitiator is selected from acetophenone, benzophenone, peroxide, phosphine, xanthone, hydroxyketone or diazonaphthoquinone, thioxanthone, α-aminoketone, benzil, or benzoin derivatives;
the prepolymer composition comprises an initiator and it is crosslinked by cationic polymerization;
when the polymerization is cationic, the constituent monomer(s) and/or dimer(s) and/or oligomers(s) and/or polymer(s) of the prepolymer layer are derivatives including chemical functions of the epoxy/oxirane, or vinyl ether, cyclic ether, thiirane, trioxane, vinyl, lactone, lactam, carbonate, thiocarbonate, or maleic anhydride type;
when the polymerization is cationic, the initiator is an acid photo-generated from a salt selected from onium salts, such as iodonium, sulfonium, pyridinium, alkoxypyridinium, phosphonium, oxonium, or diazonium salts;
the photo-generated acid may optionally be coupled to a photosensitizing compound selected from acetophenone, benzophenone, peroxide, phosphine, xanthone, hydroxyketone or diazonaphthoquinone, thioxanthone, α-aminoketone, benzil, or benzoin derivatives, as long as said photosensitizer absorbs at the desired wavelength;
the prepolymer composition comprises an initiator and it is crosslinked by an anionic polymerization reaction;
when the polymerization is anionic, the constituent monomer(s) and/or dimer(s) and/or oligomer(s) and/or polymer(s) of the prepolymer layer are derivatives of the alkyl cyanoacrylate type, epoxides/oxiranes, acrylates, or derivatives of isocyanates or polyisocyanates;
when the polymerization is anionic, the initiator is a base that is photo-generated from derivatives selected from carbamates, acyloximes, ammonium salts, sulfonamides, formamides, amine imides, α-aminoketones, and amidines;
the first polymer layer is in a solid state when the stack is brought to a temperature below its glass transition temperature or in a viscous-liquid state when the stack is brought to a temperature above its glass transition temperature, or to its highest glass transition temperature;
the first polymer layer is a block copolymer capable of nanostructuring at an assembly temperature, prior to the step of depositing the first layer of block copolymer, the method comprises a step of neutralizing the surface of the underlying substrate and, after the step of crosslinking the upper layer to form a crosslinked top coat layer, the method comprises a step of nanostructuring the block copolymer constituting the first layer by subjecting the stack obtained to an assembly temperature, said assembly temperature being lower than a temperature at which the top coat material behaves like a viscoelastic fluid, said temperature being higher than the glass transition temperature of said top coat material and, preferably, said assembly temperature being lower than the glass transition temperature of the top coat layer in its crosslinked form;
the preliminary step of neutralizing the surface of the underlying substrate consists in predrawing patterns on the surface of the substrate, said patterns being predrawn by a lithography step or a sequence of lithography steps of any nature prior to the step of depositing the first layer of block copolymer, said patterns being intended to guide the organization of said block copolymer by a technique known as chemical epitaxy or graphoepitaxy, or a combination of these two techniques, in order to obtain a neutralized or pseudo-neutralized surface;
the block copolymer comprises silicon in one of its blocks;
the first block copolymer layer is deposited to a thickness at least equal to 1.5 times the minimum thickness of the block copolymer;
the solvent of the prepolymer layer is selected from solvents or solvent mixtures, the Hansen solubility parameters of which are such that δₚ≥10 MPa^{1/2} and/or δₕ≥10 MPa^{1/2}, and with δ_{d}<25 MPa^{1/2};
the solvent of the prepolymer layer is selected from alcohols such as methanol, ethanol, isopropanol, 1-methoxy-2-propanol, ethyl lactate; diols such as ethylene glycol or propylene glycol; or from dimethyl sulfoxide (DMSO), dimethylformamide, dimethylacetamide, acetonitrile, gammabutyrolactone, water, or a mixture thereof;
the composition of the prepolymer layer comprises a multi-component mixture of monomers and/or dimers and/or oligomers and/or polymers each bearing functions ensuring crosslinking, and also various monomer units, the surface energies of which vary from one monomer unit to another;
the composition of the prepolymer layer also comprises plasticizers and/or wetting agents, added as additives;
the composition of the prepolymer layer also comprises rigid comonomers selected from derivatives including either one or more aromatic ring(s) in their structure, or monocyclic or polycyclic aliphatic structures, and having one or more chemical function(s) adapted to the crosslinking reaction targeted; and more particularly norbornene derivatives, isobornyl acrylate or methacrylate, styrene or anthracene derivatives, and adamantyl acrylate or methacrylate.

The invention also relates to a method for manufacturing a nanolithography mask by directed assembly of block copolymers, said method comprising the steps according to the method just described above and being characterized in that after the step of nanostructuring the block copolymer constituting the first layer, an additional step consists in removing the top coat layer in order to leave a film of nanostructured block copolymer of a minimum thickness, and then at least one of the blocks of said block copolymer, oriented perpendicular to the interfaces, is removed in order to form a porous film suitable for use as a nanolithography mask.

According to other optional characteristics of this method:
when the block copolymer is deposited to a thickness greater than the minimum thickness, an overthickness of said block copolymer is removed simultaneously with or successively to the removal of the top coat layer, so as to leave a film of nanostructured block copolymer of a minimum thickness, and then at least one of the blocks of said block copolymer, oriented perpendicular to the interfaces, is removed so as to form a porous film that is capable of serving as a nanolithography mask;
the top coat layer and/or the overthickness of the block copolymer and/or the block(s) of the block copolymer is/are removed by dry etching;
the steps of etching the top coat layer and/or of the overthickness of the block copolymer and one or more blocks of the block copolymer are performed successively in the same etching chamber, by plasma etching;
at the time of the step of crosslinking the top coat layer, the stack is subjected to light radiation and/or an electron beam localized on some areas of the top coat layer, so as to create crosslinked top coat areas having a neutral affinity with respect to the underlying block copolymer and non-crosslinked areas having a non-neutral affinity with respect to the underlying block copolymer;
after the localized photo-crosslinking of the top coat layer, the stack is rinsed with the solvent which allowed the deposition of the prepolymer layer so as to remove the non-irradiated areas:
another prepolymer material, which is not neutral with respect to the underlying block copolymer, is deposited in the areas which have not been irradiated beforehand and which are free of a top coat layer, and then said non-neutral prepolymer material is exposed to a stimulus so as to crosslink it in the predefined places;
at the moment of the step of annealing the stack at the assembly temperature of the block copolymer, nanodomains are formed perpendicular to the interfaces in areas facing the areas of the neutral crosslinked top coat layer, and nanodomains are formed parallel to the interfaces in areas of the block copolymer facing the areas free of crosslinked neutral top coat layer.

Finally, a subject of the invention is a polymeric stack deposited on a substrate and comprising at least two (co)polymer layers stacked one on the other, characterized in that the upper layer, known as the top coat, deposited on the first (co)polymer layer is obtained by in situ crosslinking in accordance with the method described above, said stack being intended to be used in applications selected from surface protection for the aerospace or aeronautical or motor vehicle or wind turbine sector, paints, inks, the manufacture of membranes, the production of microelectronic, optoelectronic, or microfluidic components.

More particularly, this stack is intended for applications in the field of directed self-assembly nanolithography, the first (co)polymer layer is a block copolymer and the surfaces of the layer onto which the block copolymer is deposited and of the top coat layer preferably have a neutral surface energy with respect to the blocks of the block copolymer.

Other features and advantages of the invention will become apparent upon reading the description given by way of illustrative and non-limiting example, with reference to the appended figures, which represent:

FIGS. 1A to 1C, already described, diagrams viewed in the cross section of various polymer stacks and their evolution over time,

FIG. 2, already described, a diagram viewed in the cross section of a stack of polymers according to the invention, which does not undergo any dewetting or inter-diffusion phenomena,

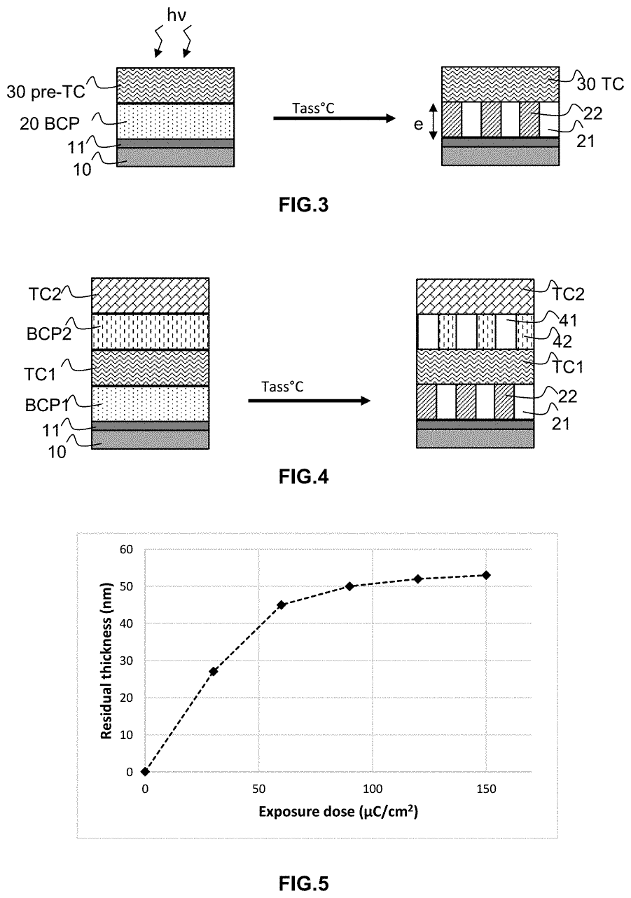

FIG. 3, a diagram viewed in the cross section of a stack according to the invention dedicated to an application in directed self-assembly (DSA) nanolithography for the production of a nanolithography mask,

FIG. 4, a diagram viewed in the cross section of another stack according to the invention dedicated to an application in directed self-assembly (DSA) nanolithography, for the creation of various patterns in a substrate,

FIG. 5, the evolution of the residual thickness of an electron beam-crosslinked PGFH copolymer as a function of the applied electron dose,

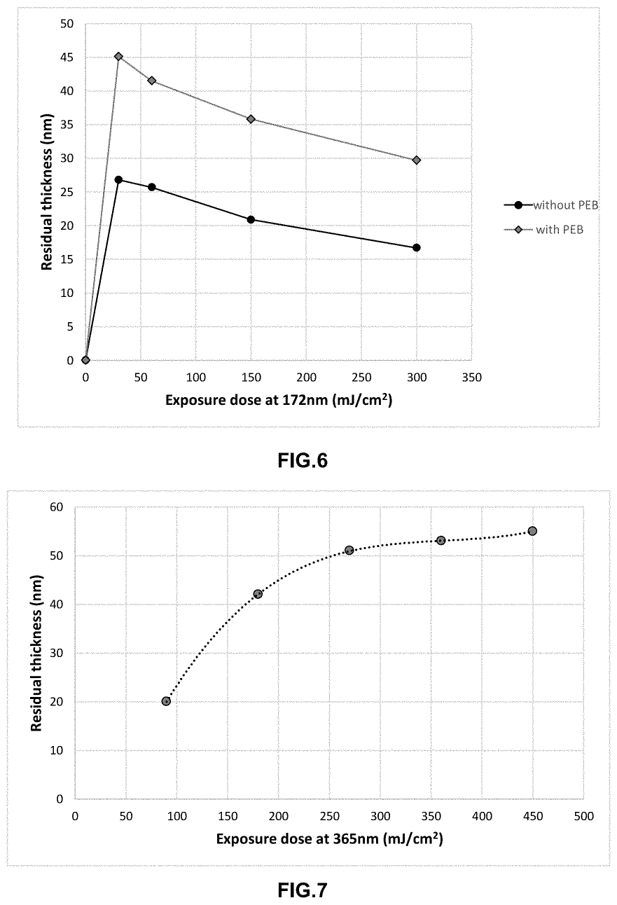

FIG. 6, the evolution of the residual thickness of a PGFH copolymer crosslinked by exposure to light radiation at 172 nm, as a function of the dose of exposure to said radiation and whether or not the film has been subjected to a post-exposure bake (PEB),

FIG. 7, the evolution of the residual thickness of a PGFH copolymer crosslinked by exposure to light radiation at 365 nm, as a function of the exposure dose to said radiation,

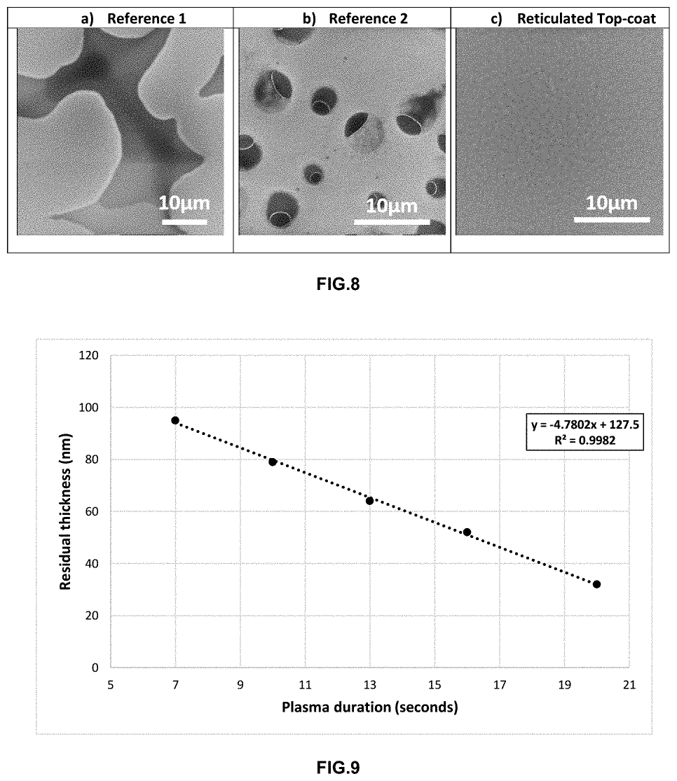

FIG. 8, scanning electron microscopy images of different reference samples, the top coat layer of which is not crosslinked, and of a sample prepared according to the invention with a crosslinked top coat layer, showing the impact of the crosslinking of the top coat layer on the different possible dewettings,

FIG. 9, the evolution of the residual thickness of a pre-crosslinked PGFH copolymer when subjected to plasma, as a function of plasma time,

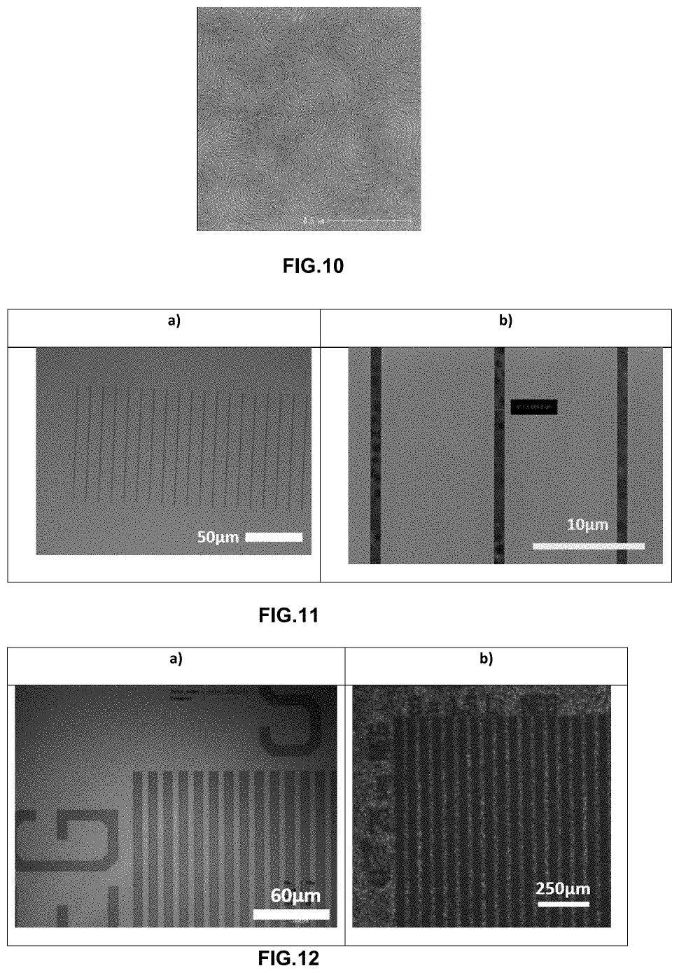

FIG. 10, a scanning electron microscopy image of a sample of a block copolymer No. 1, the self-organization of which is perpendicular to the substrate and the period of which is of the order of 18 nm, for different exposure stimuli,

FIG. 11, under letter a) an image taken by light microscopy and under letter b) an image taken by scanning electron microscopy of a sample showing patterns drawn by exposing the top coat film to an electron beam, respectively,

FIG. 12, under letter a) an image taken by light microscopy and under letter b) an image taken by scanning electron microscopy of a sample showing patterns drawn by exposing the top coat film to light radiation at 365 nm, respectively,

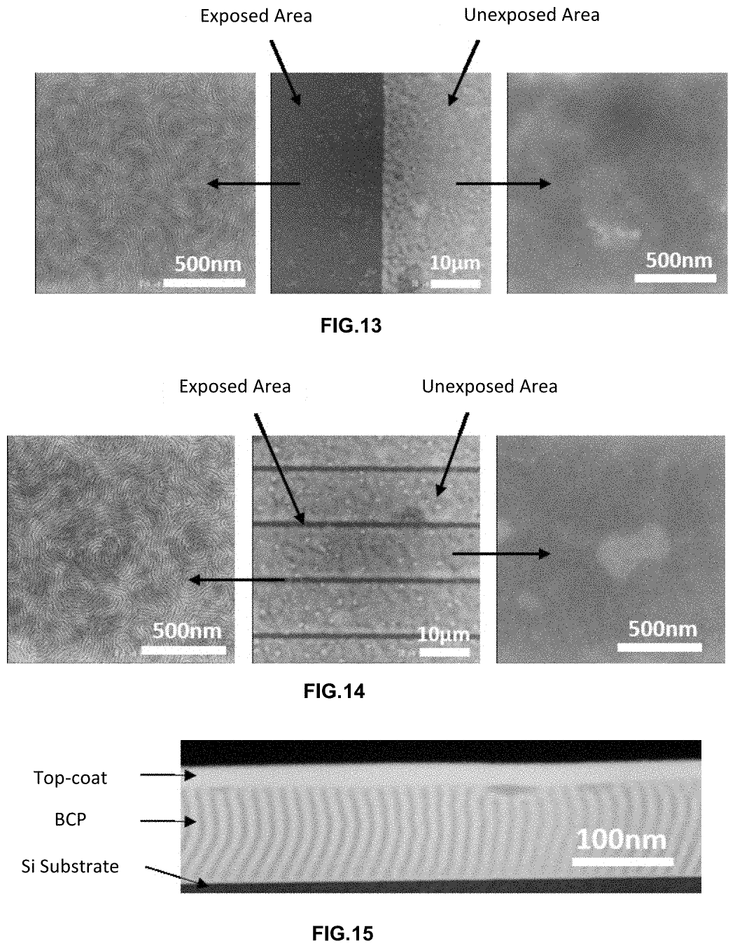

FIG. 13, scanning electron microscopy images of a sample with a top coat layer having areas exposed and unexposed to an electron beam,

FIG. 14, scanning electron microscopy images of a sample with a top coat layer having areas exposed and unexposed to a 365 nm radiation,

FIG. 15, an image of a lamellar block copolymer (BCP) No. 2 assembly, as seen in cross section by FIB-STEM preparation, after crosslinking the top coat layer,

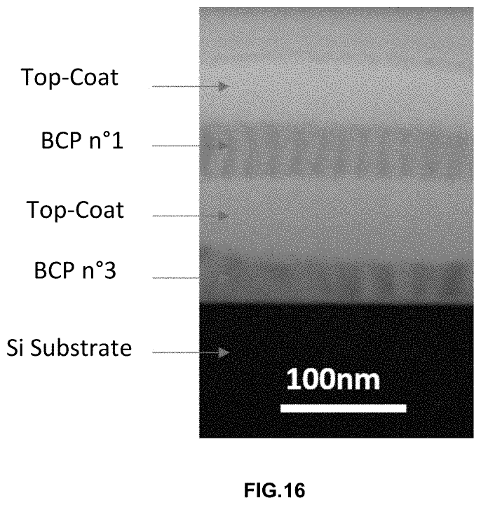

FIG. 16, an image of a stack of different block copolymer and top coat films, as seen in cross section by FIB-STEM preparation.

### DETAILED DESCRIPTION OF THE INVENTION

By “polymers” is meant either a copolymer (of the statistical, gradient, block, alternating type) or a homopolymer.

The term “monomer” as used refers to a molecule that can undergo polymerization.

The term “polymerization” as used refers to the method of transforming a monomer or a mixture of monomers into a polymer of predefined architecture (block, gradient, statistical . . . ).

By “copolymer” is meant a polymer comprising several different monomer units.

By “statistical copolymer” is meant a copolymer in which the distribution of monomer units along the chain follows a statistical law, for example Bernoullian (zero-order Markov) or first- or second-order Markovian. When the repeating units are randomly distributed along the chain, the polymers were formed by a Bernoulli process and are called random copolymers. The term random copolymer is often used, even when the statistical process that prevailed during the synthesis of the copolymer is not known.

By “gradient copolymer” is meant a copolymer in which the distribution of the monomer units varies gradually along the chains.

By “alternating copolymer” is meant a copolymer comprising at least two monomer entities which are distributed alternately along the chains.

By “block copolymer” is meant a polymer comprising one or more uninterrupted sequences of each of the separate polymer species, the polymer sequences being chemically different from each other and being bonded together by a chemical (covalent, ionic, hydrogen, or coordination) bond. These polymer sequences are also referred to as polymer blocks. These blocks have a phase segregation parameter (Flory-Huggins interaction parameter) such that, if the degree of polymerization of each block is greater than a critical value, they are not miscible with each other and separate into nanodomains.

The above-mentioned term “miscibility” refers to the ability of two or more compounds to completely mix to form a homogeneous or “pseudo-homogeneous” phase, that is to say without apparent crystalline or near-crystalline symmetry over short or long distances. The miscibility of a mixture can be determined when the sum of the glass transition temperatures (Tg) of the mixture is strictly less than the sum of the Tg of the individual compounds taken alone.

In the description, reference is made both to “self-assembly” and to “self-organization” or to “nanostructuring” to describe the well-known phenomenon of phase separation of the block copolymers, at an assembly temperature also known as the annealing temperature.

By “minimum thickness “e” of a block copolymer is meant the thickness of a film of block copolymer serving as a nanolithography mask, below which it is no longer possible to transfer the patterns of the block copolymer film into the underlying substrate with a satisfactory final aspect ratio. In general, for the block copolymers having a high phase segregation parameter χ, this minimum thickness “e” is at least equal to half the period L₀ of the block copolymer.

The term “porous film” refers to a block copolymer film in which one or more nanodomains have been removed, leaving holes, the shapes of which correspond to the shapes of the nanodomains that have been removed and may be spherical, cylindrical, lamellar, or helical.

By “neutral” or “pseudo-neutral” surface is meant a surface which, as a whole, does not have a preferential affinity with any of the blocks of a block copolymer. It thus allows an equitable or “pseudo-equitable” distribution of the blocks of the block copolymer on the surface.

Neutralization of the surface of a substrate allows to obtain such a “neutral” or “pseudo-neutral” surface.

The surface energy (noted γₓ) of a given material “x” is defined as the excess energy at the surface of the material compared to that of the material within its bulk. When the material is in liquid form, its surface energy is equivalent to its surface tension.

When reference is made to the surface energies or more specifically to the interfacial tensions of a material and of a block of a given block copolymer, these are compared at a given temperature and more particularly at a temperature which allows self-organization of the block copolymer.

By “lower interface” of a (co)polymer is meant the interface in contact with an underlying layer or substrate onto which said (co)polymer is deposited. It is noted that, in the rest of the description, when the polymer under consideration is a block copolymer to be nanostructured, intended to serve as a nanolithography mask, this lower interface is neutralized by a conventional technique, i.e. it does not have, in its overall nature, any preferential affinity for one of the blocks of the block copolymer.

By “upper interface” or “upper surface” of a (co)polymer is meant the interface in contact with an upper layer, known as the top coat and denoted TC, applied to the surface of the (co)polymer. It is noted that, in the rest of the description, when the polymer under consideration is a block copolymer to be nanostructured, intended to serve as a nanolithography mask, the upper layer of top coat TC, just like the underlying layer, preferably does not have any preferential affinity for one of the blocks of the block copolymer so that the nanodomains of the block copolymer can orient perpendicular to the interfaces at the time of annealing the assembly.

By “solvent orthogonal to a (co)polymer” is meant a solvent not capable of attacking or dissolving said (co)polymer.

By “liquid polymer” or “viscous polymer” is meant a polymer which, at a temperature greater than the glass transition temperature, has, due to its rubbery state, an increased capacity for deformation as a result of the possibility given to its molecular chains to move freely. The hydrodynamic phenomena at the origin of dewetting appear as long as the material is not in a solid state, i.e. non-deformable due to the negligible mobility of its molecular chains.

In the context of this invention, any polymeric stack system, i.e. a system comprising at least two (co)polymer layers stacked one on the other, is considered. This stack may be deposited on a solid substrate of any nature (oxide, metal, semiconductor, polymer, etc.) depending on the applications for which it is intended. The various interfaces of such a system may have a “liquid/solid” or “liquid/liquid” configuration. Thus, an upper (co)polymer layer, being in a liquid or viscous state, is deposited on an underlying (co)polymer layer which may be in a solid or liquid or viscous state, depending on the intended applications. More particularly, the underlying (co)polymer layer may be solid or liquid or viscous depending on the working temperature, relative to its glass transition temperature Tg, during the method for controlling the planarity of the stack according to the invention.

FIG. 2 illustrates such a polymeric stack. This stack is deposited, for example, on a substrate 10 and comprises, for example, two polymer layers 20 and 30 stacked one on the other. Depending on the intended applications, the first layer 20 may be not in a solid or liquid/viscous state at the time of the deposition of the second upper layer 30, known as the top coat TC. More particularly, the first layer 20 is in a solid state when the stack is brought to a temperature below its glass transition temperature or in a liquid-viscous state when the stack is brought to a temperature above its glass transition temperature. The top coat TC layer 30 is applied to the surface of the underlying layer 20, by a conventional deposition technique, for example spin coating or “spin coating”, and is in a liquid/viscous state.

The term “planarity of a polymeric stack”, within the meaning of the invention, applies to all the interfaces of the stack. The method according to the invention in fact makes it possible to control the planarity of the interface between the substrate 10 and the first layer 20 and/or the planarity of the interface between the first layer 20 and the top coat layer 30 and/or the planarity of the interface between the top coat layer 30 and air.

To avoid the appearance of a dewetting phenomenon of the top coat TC layer 30 just after its deposition onto the underlying layer 20, and to avoid an inter-diffusion phenomenon at the interface especially in the case of a liquid/liquid configuration of the interface, corresponding to the case represented in FIG. 1C, the invention advantageously consists in depositing the upper layer 30 in the form of a prepolymer composition, denoted pre-TC, comprising one or more monomer(s) and/or a dimer(s) and/or an oligomer(s) and/or a polymer(s) in solution. For the sake of simplicity, these compounds are also referred to as “molecules” or “entities” in the rest of the description. Thanks to the application of a stimulus, a crosslinking reaction takes place in situ, within the deposited pre-TC prepolymer layer, and generates the creation of a TC polymer of a high molecular mass by the crosslinking reaction of the constituent polymer chains of the deposited prepolymer layer. During this reaction, the initial size of the chains increases as the reaction propagates in the layer, thus greatly limiting the solubilization of the crosslinked top coat TC layer 30 in the underlying polymer layer 20 when the latter layer is in a liquid or viscous state, and proportionately delaying the appearance of a dewetting phenomenon.

Preferably, the prepolymer composition is formulated in a solvent that is orthogonal to the first layer 20 of polymer already present on the substrate, and comprises at least:
one monomer, dimer, oligomer, or polymer chemical entity, or any mixture of these various entities, of totally or partly identical chemical nature, and each including at least one chemical function capable of ensuring the propagation of the crosslinking reaction under the effect of a stimulus; and
one or more chemical entities capable of initiating the crosslinking reaction under the effect of the stimulus, such as a radical generator, an acid, and/or a base.

The prepolymer composition may, in one implementation variant, be used without a solvent.

Preferentially, in the context of the invention, at least one of the chemical entities of the prepolymer composition has at least one fluorine and/or silicon and/or germanium atom, and/or an aliphatic carbon-based chain of at least two carbon atoms in its chemical formula. Such entities make it possible to improve the solubility of the prepolymer composition in a solvent that is orthogonal to the underlying polymer layer 20 and/or to efficiently modify the surface energy of the top coat TC layer if need be, especially for DSA applications, and/or to facilitate wetting of the prepolymer composition on the underlying (co)polymer layer 20, and/or to reinforce the strength of the top coat TC layer with respect to a subsequent step of plasma etching.

Optionally, this prepolymer composition may further comprise in its formulation:
a chemical entity selected from an antioxidant, a weak acid or base, which is capable of trapping said chemical entity capable of initiating the crosslinking reaction, and/or
one or more additives for improving the wetting and/or the adhesion, and/or the uniformity of the upper top coat layer, and/or
one or more additives for absorbing one or more ranges of light radiations of different wavelengths, or for modifying the electrical conductivity properties of the prepolymer.

The crosslinking may be performed by any known means such as chemical crosslinking/polymerization, by means of a nucleophilic or electrophilic or other chemical species, by an electrochemical method (oxidation-reduction or by cleaving of monomers via an electron beam), by plasma, by ion bombardment or by exposure to light radiation. Preferably, the stimulus is of an electrochemical nature and applied via an electron beam or a light radiation, and even more preferably it is a light radiation.

In a particularly advantageous embodiment, the reaction of crosslinking the components of the pre-TC prepolymer layer is activated by exposing the layer to a light radiation, such as radiation in wavelength ranges from ultraviolet to infrared. Preferably, the illumination wavelength is between 10 and 1500 nm and more preferably, it is between 100 nm and 500 nm. In a particular embodiment, the light source for exposing the layer to the light radiation may be a laser device. In such a case, the wavelength of the laser will preferably be centered on one of the following wavelengths: 436 nm, 405 nm, 365 nm, 248 nm, 193 nm, 172 nm, 157 nm, or 126 nm. Such a crosslinking reaction has the advantage of being performed at ambient or moderate temperature, preferably less than or equal to 150° C. and more preferably, less than or equal to 110° C. It is also very rapid, from about a few seconds to a few minutes, preferably less than 2 minutes. Preferably, the constituent compounds of the prepolymer layer, before crosslinking, are stable in solution as long as they are protected from exposure to the light source. They are thus stored in opaque containers. When such a prepolymer layer is deposited on the underlying polymer layer 20, the constituents, which are stable in solution, are subjected to the light radiation allowing the crosslinking of the layer over a truly short period (typically less than 2 minutes). Thus, the top coat layer does not have time to dewet. Furthermore, as the reaction propagates, the size of the chains increases, which limits the solubilization and inter-diffusion problems at the interface when the latter is in a “liquid/liquid” configuration.

Regarding this photo-induced crosslinking, two major classes of compounds are distinguished for the composition of the pre-TC prepolymer layer.

A first class concerns compounds which react via a radical type species. It is thus a free-radical photo-polymerization, a possible reaction mechanism for which is illustrated by reaction (1) below.

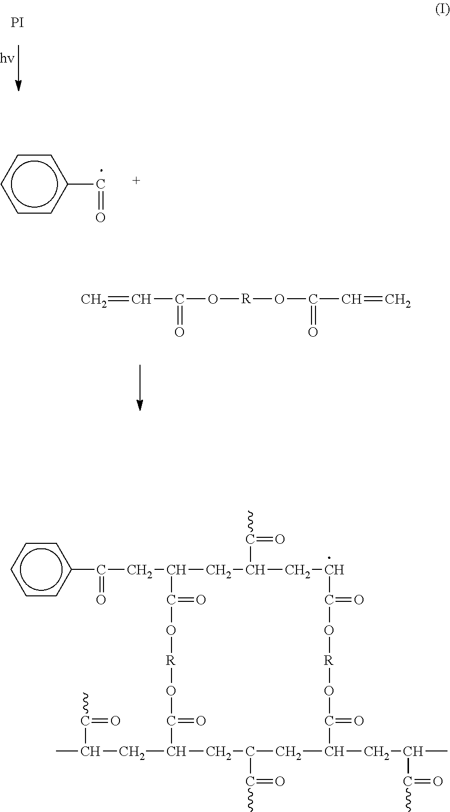

In this reaction example, the photoinitiator, denoted PI, is a photo-cleavable aromatic ketone and the telechelic/difunctional oligomer is a diacrylate with R possibly being selected from polyesters, polyethers, polyurethanes, or polysiloxanes for example.

More generally, the constituent monomer(s) and/or dimer(s) and/or oligomer(s) and/or polymer(s) of the prepolymer composition is(are) selected from acrylate or diacrylate or triacrylate or multi-acrylate, methacrylate, or multi-methacrylate, or polyglycidyl or vinyl, fluoroacrylate or fluoromethacrylate, vinyl fluoride or fluorostyrene, alkyl acrylate or methacrylate, hydroxyalkyl acrylate or methacrylate, alkylsilyl acrylate or methacrylate derivatives, unsaturated esters/acids such as fumaric or maleic acids, vinyl carbamates and carbonates, allyl ethers, and thiol-ene systems.

Preferably, but in a manner which is not limiting for the invention, the constituents of the prepolymer layer are multifunctional and have at least two chemical functions on the same molecule, which are capable of ensuring the polymerization reaction.

The composition also comprises a photoinitiator which is carefully selected depending on the selected illumination wavelength. There is a large number of radical photoinitiators with varied chemistries on the market, for instance acetophenone, benzophenone, peroxide, phosphine, xanthone, hydroxyketone or diazonaphthoquinone, thioxanthone, α-aminoketone, benzil, or benzoin derivatives.

A second class of compounds that may be included in the composition of the prepolymer layer concerns compounds which react by a cationic polymerization. This is the case, for example, for derivatives comprising chemical functions of the epoxy/oxirane, or vinyl ether, cyclic ether, thiirane, trioxane, vinyl, lactone, lactam, carbonate, thiocarbonate, and maleic anhydride type which then crosslink/polymerize by means of a photo-generated acid, denoted PGA. A mechanism for such a cationic photo-polymerization reaction of an epoxy is illustrated by reaction (II) below.

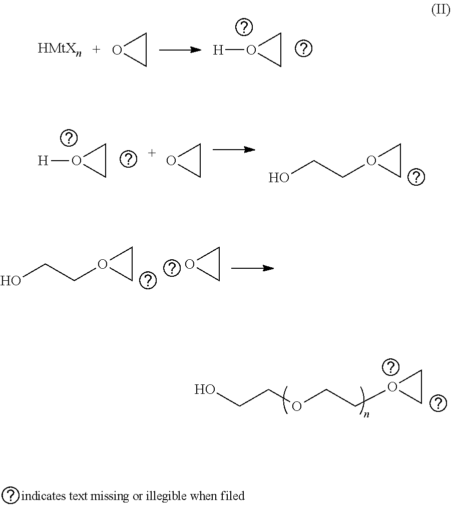

Here again, many photo-generated acid PGA precursor structures are available on the market, thus giving access to a large choice of possible light wavelengths for generating the acid, HMtXₙ, the catalyst for the crosslinking reaction. Such a precursor may be selected, for example, from onium salts, such as iodonium, sulfonium, pyridinium, alkoxypyridinium, phosphonium, oxonium, and diazonium salts. The onium salts form strong acids, HMtXₙ, under irradiation. The acid thus formed then gives a proton to the polymerizable/crosslinkable chemical function(s) of the monomer. If the monomer is sparingly basic/reactive, the acid must be strong enough to shift the equilibrium significantly towards the propagation of the crosslinking reaction and the growth of the chains, as shown in reaction (II) above.

In one variant, it is also possible to couple the photo-generated acid PGA with a photosensitizer if the selected illumination wavelength does not entirely correspond to a correct absorbance of the PGA acid. It will be possible to select such a photosensitizer, for example, from acetophenone, benzophenone, peroxide, phosphine, xanthone, hydroxyketone or diazonaphthoquinone, thioxanthone, α-aminoketone, benzil, or benzoin derivatives, as long as said photosensitizer absorbs at the desired wavelength.

Other ionic polymerizations with other types of derivatives are also possible. Thus, anionic polymerization/crosslinking reactions, for example, may also be envisaged. In this class of reaction, the reactive species is a photo-generated organic base (denoted PGB), which reacts on one or more polymerizable/crosslinkable function(s) borne by the monomer(s) of the composition of the prepolymer layer.

In this case, the photo-generated organic base PGB may be selected from compounds such as carbamates, acyloximes, ammonium salts, sulfonamides, formamides, amine imides, α-aminoketones, and amidines.

As for the monomers, dimers, oligomers, and/or polymers of the composition, they may be selected from derivatives such as alkyl cyanoacrylates, epoxides/oxiranes, acrylates, or isocyanate or polyisocyanate derivatives. In this case, the photo-generated organic base PGB may be inserted within the molecular structure of the chains constituting the polymer during the polymerization/crosslinking reaction.

The solvent for the prepolymer layer is selected so as to be entirely “orthogonal” to the polymeric system of the underlying layer so as to avoid a possible redissolution of this polymer in the solvent for the prepolymer layer during the deposition step (for example by spin coating). The solvents for each respective layer will thus be very dependent on the chemical nature of the polymer material already deposited on the substrate. Thus, if the polymer already deposited is sparingly polar/protic, its solvent being selected from sparingly polar and/or sparingly protic solvents, it will thus be possible to solubilize and deposit the prepolymer layer on the first polymer layer using solvents that are rather polar and/or protic. Conversely, if the polymer already deposited is rather polar/protic, it will be possible to select the solvents for the prepolymer layer from sparingly polar and/or sparingly protic solvents. According to a preferred embodiment of the invention, but without this being restrictive in view of what has been stated above, the prepolymer layer is deposited from polar and/or protic solvents/mixture of solvents. More precisely, the polarity/proticity properties of the different solvents are described according to Hansen nomenclature of solubility parameters (Hansen, Charles M. (2007) Hansen solubility parameters: a user's handbook, CRC Press, ISBN 0-8493-7248-8), where the designation “d” represents the forces of dispersion between solvent/solute molecules, “bp” represents the energy of dipole forces between molecules, and “bn” represents the energy of possible hydrogen bonding forces between molecules, the values of which are tabulated at 25° C. In the context of the invention, “polar and/or protic” is defined as a solvent/molecule or solvent mixture having a polarity parameter such that δₚ≥10 MPa^{1/2} and/or a hydrogen bonding parameter such that δₕ≥10 MPa^{1/2}. Similarly, a solvent/molecule or solvent mixture is defined as “low polar and/or protic” when the Hansen solubility parameters are such that δₚ<10 MPa^{1/2} and/or δₕ<10 MPa^{1/2}, and preferably δₚ≤8 MPa^{1/2}, and/or a hydrogen bonding parameter such that δₕ≤9 MPa^{1/2}.

According to a preferred but non-restrictive embodiment of the invention, the solvent for the prepolymer layer is selected from the compounds having a hydroxy function, for instance alcohols such as methanol, ethanol, isopropanol, 1-methoxy-2-propanol, ethyl lactate; or diols such as ethylene glycol or propylene glycol; or from dimethyl sulfoxide (DMSO), dimethylformamide, dimethylacetamide, acetonitrile, gammabutyrolactone, water, or a mixture thereof.

More generally, in the context of one of the preferential but non-exhaustive embodiments of the invention, the various constituents of the prepolymer layer are soluble and stable in solvents, the Hansen solubility parameters of which are such that δ₉≥10 MPa^{1/2} and/or δₕ≥10 MPa^{1/2} as defined previously, and with the dispersion parameter δ_{d}<25 MPa^{1/2}.

The reaction of crosslinking by irradiation of the prepolymer layer may take place at a moderate temperature, much lower than the glass transition temperature of the underlying polymer layer 20, so as to promote the diffusion of the reactive species and thus to increase the rigidity of the crosslinked network. Typically, the activation of the photoinitiator or of the photo-generated acid PGA or of the photo-generated base, may be initiated at a temperature below 50° C. and preferably below 30° C., over a time typically less than 5 minutes and preferably less than 1 minute. Next, in a second stage, the crosslinking reaction may be propagated by bringing the stack to a temperature preferably below 150° C. and more preferably below 110° C., so as to promote the diffusion of the reactive species (protons, radicals, etc.) within the prepolymer layer, for a time of less than 5 minutes, and preferably less than 2 minutes.

According to one variant of the invention, the light irradiation of the prepolymer layer is performed directly on a stack brought to the desired temperature, preferably below 110° C., to optimize the total reaction time.

Before the crosslinking reaction, the top coat TC layer may be in the form of a block or statistical, random, gradient, or alternating copolymer, which may have a linear or star structure when one of the comonomers is multifunctional, for example.

The invention as described above applies to any type of polymeric stack. Among the diverse and varied applications of such stacks, the Applicant also focused on directed self-assembly, or DSA, nanolithography. However, the invention is not limited to this example, which is given for illustrative and in no way limiting purposes. Indeed, in the context of such an application, the top coat TC upper layer must also satisfy other additional requirements, in order especially to allow the nanodomains of the underlying block copolymer to orient perpendicular to the interfaces.

FIG. 3 illustrates such a polymeric stack dedicated to an application in the organic electronics field. This stack is deposited on the surface of a substrate 10. The surface of the substrate is neutralized, or pseudo-neutralized, beforehand by a conventional technique. To do this, the substrate 10 does or does not include patterns, said patterns being predrawn by a lithography step or a sequence of lithography steps of any nature prior to the step of depositing the first layer (20) of block copolymer (BCP), said patterns being intended to guide the organization of said block copolymer (BCP) by a technique known as chemical epitaxy or graphoepitaxy, or a combination of these two techniques, in order to obtain a neutralized surface. One particular example consists in grafting a layer 11 of a statistical copolymer including an astutely selected ratio of the same monomers as those of the block copolymer BCP 20 deposited on top. The layer 11 of the statistical copolymer makes it possible to balance the initial affinity of the substrate for the block copolymer BCP 20. The grafting reaction can be obtained by any thermal, photochemical, or oxidation-reduction means, for example. Next, a top coat TC layer 30 is deposited on the layer of block copolymer BCP 20. This TC layer 30 should not have any preferential affinity with respect to the blocks of the block copolymer 20 so that the nanodomains 21, 22 which are created at the time of annealing at the assembly temperature Tass orient perpendicular to the interfaces, as illustrated in FIG. 3. The block copolymer is necessarily liquid/viscous at the assembly temperature, so it can nanostructure. The top coat TC layer 30 is deposited on the block copolymer 20 in a liquid/viscous state. The interface between the two polymer layers is thus in a liquid/liquid configuration which favors inter-diffusion and dewetting phenomena.

Preferably, the assembly temperature Tass of the block copolymer 20 is lower than the glass transition temperature Tg of the top coat TC layer 30 in its crosslinked form or at least lower than a temperature at which the top coat TC material behaves as a viscoelastic fluid. This temperature is then in a temperature range, corresponding to this viscoelastic behavior, which is above the glass transition temperature Tg of the top coat TC material.

As regards the layer 20 of block copolymer to be nanostructured, also denoted BCP, it comprises “n” blocks, n being any integer greater than or equal to 2. The block copolymer BCP is more particularly defined by the following general formula:

A-b-B-b-C-b-D-b- . . . -b-Z

where A, B, C, D, . . . , Z are blocks “i” . . . “j” representing either pure chemical entities, i.e. each block is a set of monomers of identical chemical natures, polymerized together, or a set of comonomers, copolymerized together, totally or partly in the form of a block or statistical or random or gradient or alternating copolymer.

Each of the blocks “i” . . . “j” of the block copolymer BCP to be nanostructured can thus potentially be written in the form: i=aᵢ-co-bᵢ-co- . . . -co-zᵢ, with i≠ . . . ≠j, in all or part.

The volume fraction of each entity aᵢ . . . zᵢ can be from 1% to 99%, by monomer units, in each of the blocks i . . . j of the block copolymer BCP.

The volume fraction of each of the blocks i . . . j can be from 5% to 95% of the block copolymer BCP.

The volume fraction is defined as being the volume of an entity relative to that of a block, or the volume of a block relative to that of the block copolymer.

The volume fraction of each entity of a block of a copolymer, or of each block of a block copolymer, is measured in the manner described below. Within a copolymer in which at least one of the entities, or one of the blocks if it is a block copolymer, includes several comonomers, it is possible to measure, by proton NMR, the mole fraction of each monomer in the entire copolymer, and then to work back to the mass fraction by using the molar mass of each monomer unit. In order to obtain the mass fractions of each entity of a block, or each block of a copolymer, it is then enough to add the mass fractions of the constituent comonomers of the entity or of the block. The volume fraction of each entity or block can then be determined from the mass fraction of each entity or block and from the density of the polymer formed by the entity or block. However, it is not always possible to obtain the density of polymers, the monomers of which are copolymerized. In this case, the volume fraction of an entity or of a block is determined from its mass fraction and from the density of the compound which is predominant by mass in the entity or block.

The molecular mass of the block copolymer BCP can be from 1000 to 500,000 g·mol⁻¹.

The block copolymer BCP may have any type of architecture: linear, star (three or multiple arms), grafted, dendritic, comb.

Each of the blocks i . . . j of a block copolymer has a surface energy, denoted γᵢ . . . γⱼ, which is specific to it and which depends on its chemical constituents, i.e. on the chemical nature of the monomers or comonomers composing it. Likewise, each of the constituent materials of a substrate have their own surface energy value.

Each of the blocks i . . . j of the block copolymer also has an interaction parameter of Flory-Huggins type, denoted: χᵢₓ, when it interacts with a given material “x”, which can be a gas, a liquid, a solid surface, or another polymer phase for example, and an interfacial energy denoted “γᵢₓ”, with γᵢₓ=γᵢ−(γₓ cos θᵢₓ), where θᵢₓ is the contact angle between the materials i and x. The interaction parameter between two blocks i and j of the block copolymer is thus denoted χᵢⱼ.

There is a relationship linking γᵢ and the Hildebrand solubility parameter δᵢ of a given material i, as described in the document Jia & al., Journal of Macromolecular Science, B, 2011, 50, 1042. In point of fact, the Flory-Huggins interaction parameter between two given materials i and x is indirectly linked to the surface energies γᵢ and γₓ specific to the materials, and it is consequently possible to speak either in terms of surface energies, or in terms of interaction parameter to describe the physical phenomenon occurring at the interface of the materials.

When we speak of surface energies of a material and of those of a given block copolymer BCP, it is implied that the surface energies are compared at a given temperature, and this temperature is that (or forms at least part of the temperature range) which allows the self-organization of the BCP.

In the same manner as described previously for any stack of polymers, the upper layer 30, which is deposited on the layer 20 of block copolymer BCP, is in the form of a prepolymer composition, denoted pre-TC, and comprises one or more monomer(s) and/or dimer(s) and/or oligomer(s) and/or polymer(s) in solution. By means of the application of a stimulus, in this instance a light radiation, the wavelength of which ranges from ultraviolet to infrared, between 10 nm to 1500 nm, and preferably between 100 nm and 500 nm, a crosslinking or polymerization reaction of the constituent molecular chains of the prepolymer layer takes place in situ, in the deposited pre-TC prepolymer layer, and gives rise to the creation of a TC polymer of a high molecular mass. A single polymer chain is then created, which is extremely sparingly miscible with the underlying block copolymer BCP, thus greatly limiting the solubilization of the top coat TC layer 30 in the underlying layer 20 of block copolymer BCP and proportionately delaying the appearance of a dewetting phenomenon. Thus, the photo-crosslinking of the top coat TC layer 30 makes it possible to avoid not only the problems of inter-diffusion and dewetting of the top coat TC layer 30 on the underlying block copolymer BCP 20, but also to stabilize the block copolymer layer 20 so that it does not dewet from its substrate 10. The crosslinking of the top coat TC layer 30 thus makes it possible to obtain a stack, the surface of which is perfectly flat, with perfectly clear substrate/block copolymer (substrate/BCP) and block copolymer/top coat (BCP/TC) interfaces.

Such a top coat TC layer thus crosslinked has a surface energy, at the temperature allowing the self-assembly of the underlying block copolymer BCP 20, between 10 and 50 mN/m, preferably between 20 and 45 mN/m and more preferably between 25 and 40 mN/m.

However, this crosslinking reaction involves chemical species, such as carbanions, carbocations, or radicals, which are more reactive than a simple non-crosslinkable top coat layer. It is consequently possible, in some cases, for these chemical species to be able to diffuse and possibly degrade the block copolymer BCP 20. Such diffusion is a function of the temperature of propagation of the reaction and the nature of the chemical species involved. However, it is very limited, over a thickness of at most a few nanometers and in all cases less than 10 nm, due to the immiscible nature of the top coat TC layer 30 and the block copolymer BCP layer 20. As a result of such diffusion, the effective thickness of the block copolymer layer may thereby be reduced. To compensate for this possible diffusion, the block copolymer BCP 20 can be deposited to a greater thickness (e+E), for example at least 1.5 times the minimum thickness e of the block copolymer. In this case, after nanostructuring and at the time of the removal of the top coat TC layer, the block copolymer overthickness E is also removed to retain only the lower part, of a minimum thickness e, of the block copolymer.

In any case, if any, the diffusion is limited to a thickness of a few nanometers at most, it forms an intermediate layer comprising an intimate mixture of the constituents of the copolymer BCP 20 block and the top coat TC layer 30. This intermediate layer then has an intermediate surface energy, between that of the pure top coat TC 30 and that of the average surface energy of the blocks of the block copolymer BCP 20, so that it has no particular affinity with one of the blocks of the block copolymer BCP and therefore makes it possible to orient the nanodomains of the underlying block copolymer BCP 20 perpendicularly to the interfaces.

Advantageously, the deposition of a prepolymer layer followed by its crosslinking, makes it possible to be free of problems linked to the need to synthesize a high molecular weight top coat material. It is indeed sufficient to synthesize monomers, dimers, oligomers, or polymers, the molecular weights of which are much more reasonable, typically of the order of one order of magnitude less, thus limiting the difficulties and operating conditions specific to the chemical synthesis step. The crosslinking of the prepolymer composition then allows these high molecular weights to be generated in situ.

Depositing a prepolymer composition, comprising monomers, dimers, oligomers, or polymers of a molecular mass much lower than a non-crosslinked top coat material, also makes it possible to broaden the possible range of solvents for the top coat TC material, where these solvents have to be orthogonal to the block copolymer BCP.

Advantageously, the pre-TC prepolymer composition may comprise fluorinated monomers, dimers, oligomers, or polymers, soluble in alcoholic solvents, for instance methanol, ethanol or isopropanol, 1-methoxy-2-propanol, ethyl lactate; in diols such as ethylene glycol or propylene glycol or in dimethyl sulfoxide (DMSO), dimethylformamide, dimethylacetamide, acetonitrile, gammabutyrolactone, water, or a mixture thereof in which the block copolymers are generally insoluble.

In the same manner as described above, two major classes of compounds are distinguished for the composition of the pre-TC prepolymer layer. A first class concerns compounds which react via a radical type species. This is a free-radical photo-polymerization. The constituent monomer(s) and/or dimer(s) and/or oligomer(s) and/or polymer(s) of the prepolymer composition is(are) selected from acrylate or diacrylate or triacrylate or multi-acrylate, methacrylate or multi-methacrylate, or vinyl, fluoroacrylate or fluoromethacrylate, vinyl fluoride or fluorostyrene, alkyl acrylate or methacrylate, hydroxyalkyl acrylate or methacrylate, alkylsilyl acrylate or methacrylate derivatives, unsaturated esters/acids such as fumaric or maleic acids, vinyl carbamates and carbonates, allyl ethers, and thiol-ene systems. The composition also comprises a photoinitiator which is carefully selected, depending on the selected illumination wavelength, from acetophenone, benzophenone, peroxide, phosphine, xanthone, hydroxyketone, thioxanthone, α-aminoketone, benzil, and benzoin derivatives for example.

In another embodiment, the compounds of the prepolymer composition react by cationic polymerization and are selected from derivatives including chemical functions of the epoxy/oxirane, or vinyl ether, cyclic ether, thiirane, trioxane, vinyl, lactone, lactam, carbonate, thiocarbonate, maleic anhydride type, which then crosslink by means of a photo-generated acid PGA. In this case, the prepolymer composition also comprises a photo-generated acid PGA precursor, for generating the acid catalyst for the crosslinking reaction under illumination, which may be selected from onium salts, such as iodonium, sulfonium or pyridinium or alkoxypyridinium, phosphonium, oxonium, diazonium salts.

In order to further limit a possible dewetting phenomenon of the top coat TC layer 30, the rigidity (measured, for example, by estimating the Young's modulus of the top coat TC once crosslinked) and the glass transition temperature of the top coat layer can be reinforced by introducing, in the pre-TC prepolymer composition, rigid co-monomers selected from derivatives having either one or more aromatic ring(s) in their structure, or mono- or multi-cyclic aliphatic structures, and having one or more chemical function(s) adapted to the crosslinking reaction targeted. More particularly, these rigid comonomers are selected from derivatives of norbornene, isobornyl acrylate or methacrylate, styrene, anthracene derivatives, adamantyl acrylate or methacrylate. The rigidity and the glass transition temperature of the top coat layer may also be reinforced by multiplying the possible crosslinking points of the components, with oligomer chains or multifunctional monomer derivatives, for instance polyglycidyl derivatives or diacrylate or triacrylate or multi-acrylate derivatives, derivatives having one or more unsaturations, such as “sp2” or “sp” hybridized carbon atoms, in their chemical formula.

In any case, care must be taken to ensure that the light wavelength used for the crosslinking of the top coat TC layer 30 does not interfere or interferes only very little with the components of the underlying block copolymer BCP 20, so as to avoid a possible photo-induced degradation thereof. The choice of the photoinitiator, of the photo-generated acid or of the photo-generated base will thus have to be made so that the light radiation does not degrade the block copolymer. However, in general, the photo-crosslinking is particularly efficient, with a high quantic yield, even at a low energy dose (typically from a few millijoules per square centimeter (mJ/cm²) to a few tens of mJ/cm², for example for doses equivalent to the lithography processes commonly used for exposure of photosensitive resins at 193 nm), as opposed to the degradation of the block copolymer at the same wavelength which generally requires a higher dose (typically, for example, from 200 mJ/cm² to 1000 mJ/cm² at 193 nm for polymethyl methacrylate PMMA). Consequently, even with a coating with a top coat TC layer photo-crosslinked at a wavelength of degradation of the underlying block copolymer, the energy dose remains low enough so as not to deteriorate the block copolymer BCP. Preferably, the energy dose during the photo-crosslinking is less than or equal to 200 mJ/cm², more preferably it is less than or equal to 100 mJ/cm² and even more preferably, it is less than or equal to 50 mJ/cm².

In order to obtain a crosslinked top coat TC layer 30 which is neutral with respect to the underlying block copolymer 20, i.e. which does not have any particular affinity for each of the blocks of the block copolymer, the pre-TC prepolymer composition preferably comprises a multi-component mixture of derivatives all bearing functions that ensure the crosslinking, but different chemical groups. Thus, for example, the composition may comprise one component with fluorinated groups, another with oxygen-based groups, etc. so as to be able to finely modulate the surface energy specific to the top coat TC layer once photo-crosslinked. Thus, among the molecules reacting by cationic photo-polymerization with photo-generated acids PGA to form a crosslinked TC layer, mention may be made, for example, of oligomers formed from a monomer of a low surface energy, for instance a fluoro acrylate, a monomer of a medium to high surface energy, for instance a hydroxylated acrylate, and a crosslinkable group, via an acid reaction by means of the use of a photo-generated acid, for instance an epoxy. In this case, the ratio of monomer of a low surface energy/monomer of a high surface energy, weighted by the proportion of crosslinkable monomer, conditions the neutrality of the crosslinked top coat TC layer relative to the underlying block copolymer BCP. The content of crosslinkable groups relative to the nature of the molecules of the prepolymer composition conditions the final rigidity of the crosslinked top coat TC layer. Finally, the physicochemical structure of the photo-generated acid PGA conditions its activation wavelength and its solubility.

However, in the context of directed self-assembly nanolithography applications, it should be ensured that the top coat TC, once formed, does not correspond to a porous or multi-phase network, so as to avoid possible problems of inhomogeneity/demixing of the top coat TC for the underlying block copolymer BCP. To this end, the pre-TC prepolymer composition may be formed from a prepolymer/photoinitiator binary mixture and optional plasticizers or wetting agents as additives, if need be. In the context of other applications, such as the manufacture of membranes or biocompatible implants, for example, it may instead be advantageous for the top coat TC, once formed, to correspond to such a porous or multi-phase network.

To be able to manufacture a nanolithography mask, for example, once the top coat TC layer has been crosslinked, the stack obtained, having a clear BCP/TC interface and a perfectly flat surface, is subjected to annealing, preferably heat annealing, at an assembly temperature Tass, for a given time, preferably less than 60 minutes and more preferably less than 5 minutes, so as to cause nanostructuring of the block copolymer. The nanodomains 21, 22 which form then orient perpendicular to the neutralized interfaces of the block copolymer BCP.

Next, once the block copolymer has organized, the top coat TC layer can be removed.

One way of removing the crosslinked top coat TC layer consists in using dry etching, such as plasma, for example with a suitable gas chemistry, such as a predominant oxygen base in a mixture with a gas that is rather inert such as He, Ar, N₂, for example. Such dry etching is all the more advantageous and easier to perform if the underlying block copolymer BCP 20 contains, for example, silicon in one of its blocks, which then acts as an etch-stopping layer.

Such dry etching may also be interesting in the case where the underlying block copolymer BCP has been deposited with an overthickness E and where not only the top coat TC layer must be removed, but also the overthickness E of block copolymer. In this case, the chemistry of the constituent gases of the plasma will have to be adjusted depending on the materials to be removed so as not to have any particular selectivity for a block of the block copolymer BCP. The top coat TC layer and the overthickness E of the block copolymer BCP can then be removed simultaneously or successively, in a same etching chamber, by plasma etching by adjusting the chemistry of the gases depending on the constituents of each of the layers to be removed.

Similarly, at least one of the blocks 21, 22 of the block copolymer BCP 20 is removed so as to form a porous film that is capable of serving as a nanolithography mask. This removal of the block(s) may also be performed in the same dry etching chamber, following the removal of the top coat TC layer and the optional overthickness E of block copolymer.

It is also possible to create stacks comprising a succession of these two alternating layers of block copolymer BCP and top coat TC. An example of such a stack is illustrated in the diagram of FIG. 4 which shows the first stack already described comprising a substrate 10, the surface 11 of which is neutralized beforehand, a first layer of block copolymer BCP1, and then a first top coat layer TC1. Next, once the top coat layer TC1 has crosslinked, a second block copolymer BCP2 is deposited on the first top coat layer. This second block copolymer BCP2 may be of a nature identical to or different from that of the first block copolymer and makes it possible to create patterns, at its assembly temperature, different from those of the first block copolymer BCP1.

In this case, it is also necessary for the first top coat layer TC1 to be neutral with respect to the blocks of the second block copolymer BCP2. If it is not the case, its surface should be neutralized, by grafting with a statistical copolymer, for example. Next, a second prepolymer layer pre-TC2 is deposited on the second block copolymer BCP2 and illuminated so as to cause a crosslinking reaction and rigidify it. This second crosslinked top coat layer TC2 must also be neutral with respect to the second block copolymer BCP2. The assembly temperatures of the two block copolymers BCP1 and BCP2 may be identical or different. If they are identical, a single annealing operation is enough to cause structuring of the two block copolymers simultaneously. If they are not identical, two annealing operations are necessary to structure them each in turn. And so on, several alternating layers of block copolymers and of top coat may thus be deposited on top of each other. Such stacks of polymers may be used in microelectronic or optoelectronic applications, for instance Bragg mirrors, or for creating specific anti-reflective layers. Thereafter, optionally, several successive etching steps make it possible to transfer the various patterns from the various block copolymers into the underlying substrate. These etching steps are then preferably performed by plasma by adjusting the chemistry of the gases at each layer depending on the constituents of the layer.

Another major additional advantage of the present invention lies in the possibilities of selectivity of the method via the photo-generated species. Thus, if a local light source, for instance of the laser type, is used to perform the irradiation of the pre-TC prepolymer layer, then it becomes possible to define areas on the stack where the pre-TC prepolymer layer will be able to be crosslinked, by photo-irradiation, and other areas where the pre-TC prepolymer layer will remain in the molecular state since it is not irradiated. Such a localized irradiation at the surface of the top coat TC may also be performed by means of a lithography mask, for example, and overall irradiation of the surface covered with said mask.

In one embodiment variant, such a selectivity allowing the creation of crosslinked areas and of non-crosslinked areas may also be obtained by means of an electron beam.

In the context of applying the method according to the invention to directed self-assembly nanolithography, the crosslinked areas of top coat have a neutral affinity with respect to the underlying block copolymer, whereas the areas of non-irradiated top coat may have a preferential affinity for at least one of the blocks of the underlying block copolymer. It then becomes possible to define areas of interest on the same stack, where the patterns of the underlying block copolymer BCP will be perpendicular to the interfaces, in areas facing the areas of the neutral top coat which are irradiated and neutral with respect to the blocks of the block copolymer, and other areas, facing the non-irradiated areas, where the patterns of the block copolymer will, on the other hand, be oriented parallel to the interfaces, where it is then not possible for these to be transferred into the underlying substrate during subsequent etching steps.

To do this, the following method may simply be performed. The layer of pre-TC prepolymer is deposited, and then areas of interest of this layer are irradiated for example through a lithography mask. The layer obtained is then rinsed in the solvent which served for its deposition, for example, the solvent itself being orthogonal to the block copolymer. This rinsing makes it possible to remove the non-irradiated areas. Optionally, another prepolymer material, which is not neutral with respect to the underlying block copolymer, may be deposited in the areas which have not been irradiated beforehand and which have been rinsed, and which are thus free of top coat layer, and then said non-neutral prepolymer material is exposed to a stimulus, which may be a light radiation or another stimulus selected from an electrochemical process, plasma, ion bombardment, or chemical species, so as to crosslink it in the predefined places. The stack is then subjected to annealing at the assembly temperature so that the block copolymer becomes structured. In this case, the nanodomains facing the irradiated and crosslinked areas of the top coat TC layer, and neutral with respect to the block copolymer, are oriented perpendicular to the interfaces, whereas the nanodomains facing areas free of crosslinked and neutral top coat are oriented parallel to the interfaces.

The following examples illustrate the scope of the invention in a non-limiting manner:

### Example 1: Block Copolymers Used

The poly(1,1 dimethylsilacyclobutane)-block-polystyrene (“PDMSB-b-PS”) block copolymers used were synthesized by sequential anionic polymerization, as already reported in the prior art (K. Aissou & al., Small, 2017, 13, 1603777). The block copolymer No. 1 more specifically used here has a number average molar mass (Mn) of 17,000 g/mol, with a polydispersity index of 1.09 measured by steric exclusion chromatography (SEC) with polystyrene standards. The characterization shows a composition of 51% (by mass) PS and 49% (by mass) PDMSB. The block copolymer No. 2 more specifically used here has a number average molar mass (Mn) of 14,000 g/mol, with a polydispersity index of 1.07. The block copolymer No. 3 more specifically used here has a number average molar mass (Mn) of 19,000 g/mol, with a polydispersity index of 1.09. The characterization shows a composition of 52% (by mass) PS and 48% PDMSB. The period of the block copolymer No. 1 is measured at ˜18 nm, that of No. 2 is measured at ˜14 nm, that of BCP No. 3 at ˜24 nm, via a fast Fourier transform (FFT) of images taken by scanning electron microscopy (SEM), on self-organized films. As described in the literature cited, the “PDMSB” block contains silicon in its composition.

### Example 2: Synthesis of Surface Passivation Layers and Top Coat Layers

The copolymers or homopolymers used in the context of the invention have been synthesized by standard methods such as NMP (nitroxide mediated polymerization, for example with an initiator such as Arkema's initiator marketed under the name BlocBuilder®) or a conventional radical method (with an initiator such as azobisisobutyronitrile), known to the one skilled in the art. The number average molar mass obtained are typically of the order of Mn˜5,000-10,000 g/mol. The polymer used as a neutralizing underlayer is a 2-ethylhexyl polymethacrylate homopolymer. The copolymer used as a top coat layer has a copolymer architecture of the poly(glycidyl methacrylate-co-trifluoroethyl methacrylate-co-hydroxyethyl methacrylate) type, subsequently abbreviated to “PGFH”, of variable “GFH” compositions, ranging from 25/3/72 to 25/47/28, by mass compositions. In the absence of other specifications explicitly mentioned, the results obtained being equivalent for the different compositions mentioned above, only those concerning the composition 25/37/38 are detailed below. A PGFH copolymer is also synthesized, with a mass composition of 25/0/75.

### Example 3: Solvents for Top Coat Copolymers

The various copolymers synthesized according to Example 2 of the PGFH type are all soluble entirely in alcoholic solvents up to 10% by weight or less, such as methanol, ethanol, isopropanol, PGME (propylene glycol methyl ether), or ethyl lactate, as well as in mixtures of these same solvents in any proportions. The block copolymers described in Example No. 1 are not soluble in the same solvents or mixtures thereof.

Solubility parameters for these different solvents are available in the literature (Hansen, Charles (2007). Hansen Solubility Parameters: A user's handbook, Second Edition. Boca Raton, Fla.: CRC Press. ISBN 978-0-8493-7248-3), but they are grouped in Table 1 below for convenience:

TABLE 1

| | | Hansen parameters at 25° C. ((MPa)^{1/2}) | | |
|---|---|---|---|---|
| Solvent | CAS No. | δD | δP | δH |
| methanol | 67-56-1 | 15.1 | 12.3 | 22.3 |
| ethanol | 64-17-5 | 15.8 | 8.8 | 19.4 |
| PGME | 107-98-2 | 15.6 | 6.3 | 11.6 |
| isopropanol | 67-63-0 | 15.8 | 6.1 | 16.4 |
| ethyl lactate | 687-47-8 | 16 | 7.6 | 12.5 |

When these solvents are used to solubilize PGFH copolymers with their additives, spin-coated deposits on block copolymers (PDMSB-b-PS) No. 1 or No. 2 show excellent uniformity.

### Example 4: Example of a Top Coat Crosslinking Via Different Stimuli

Electron Beam (e-Beam) Crosslinking

The equipment used for e-beam lithography is a JEOL 6300FS instrument operating at 100 kV, the electron beam intensity of which is set at 5 nA. A different exposure dose is tested for each sample, from 30 μC/cm² to 180 μC/cm², in 30 μC/cm² steps.

A 2 wt. % PGFH copolymer solution is made in absolute ethanol. A 2 wt. % solution of triphenylsulphonium trifluoromethane sulfonate (subsequently abbreviated “TPST”) is prepared, also in absolute ethanol. A mixed solution of PGFH and TPST is then prepared at 90 wt. % PGFH and 10 wt. % TPST. The solution thus obtained is filtered on a PTFE (polytetrafluoroethylene) filter with a porosity of 200 nm, and then dispensed by spin-coating at 2,000 revolutions per minute (rpm) on a silicon substrate with a side of 3 cm, so as to obtain a ˜60 nm thick, homogeneous film. A soft bake is then carried out at 60° C. for 1 minute to remove residual traces of solvent from the copolymer film, and then the sample is exposed to an electron beam at a precise dose to draw rectangular patterns of 200 μm×100 μm, which are 400 μm apart. After exposure, a bake (“post-exposure bake” in English, or PEB) is carried out at 90° C. for 2 minutes to allow the diffusion of the electro-generated acid into the PGFH film. The sample is then rinsed in a bath of absolute ethanol for 1 minute to remove unexposed areas from the substrate, and then the residual solvent is removed under nitrogen flow. The sample thus prepared is then cleaved so that the fracture made cuts the patterns drawn, and then the residual thickness corresponding to the crosslinked PFGH copolymer is estimated by scanning electron microscopy via a sectional view of the patterns drawn. The thickness values thus determined are shown in the graph in FIG. 5, which represents the evolution of the thickness of residual crosslinked PGFH as a function of the electron dose applied.

This graph thus allows to demonstrate that the PGFH copolymer can be crosslinked via an electron beam, and that if an area of the film is not exposed to the beam, it will be removed during the solvent rinse step. The example therefore shows that areas of the film can be specifically selected to undergo a crosslinking reaction. It should be noted that the sensitivity of the material to the beam can be easily modified by playing on various parameters well known to the man skilled in the art, such as the ratio of constituents, the chemical nature of the sulfonium salt, etc.

Crosslinking by a Photochemical Process at λ=172 nm

The UV unit used was designed by the company SCREEN SPE. It comprises an enclosure conditioned in an inert atmosphere (constant flow of nitrogen), irradiated by a UV lamp delivering a power of 30 W·cm⁻² at a wavelength of 172 nm. The samples are first placed in the sealed enclosure, and then the atmosphere is conditioned for a few minutes to ensure the absence of oxygen, and the lamp is turned on for a defined time corresponding to a given light dose.

A 2 wt. % PGFH copolymer solution is made in absolute ethanol. A 2 wt. % solution of triphenylsulphonium trifluoromethane sulfonate (subsequently abbreviated “TPST”) is prepared, also in absolute ethanol. A mixed solution of PGFH and TPST is then prepared at 90 wt. % PGFH and 10 wt. % TPST. The solution thus obtained is filtered on a PTFE filter with a porosity of 200 nm, and then dispensed by spin-coating at 2,000 revolutions per minute (rpm) on a silicon substrate with a side of 3 cm, so as to obtain a ˜60 nm thick, homogeneous film. A soft bake (“soft bake” in English) is then carried out at 60° C. for 1 minute to remove residual traces of solvent from the copolymer film, and the sample is then placed in the UV unit enclosure and subjected to a specific dose of light radiation. Subsequently, a post-exposure bake (PEB) is carried out or not at 90° C. for 2 minutes on a single hot plate to allow diffusion of the photo-generated acids into the copolymer film, and then the sample is rinsed in a bath of absolute ethanol for 2 minutes to remove non-crosslinked copolymer chains and the residual solvent is removed under nitrogen flow. The residual film thickness corresponding to the photo-crosslinked PGFH copolymer is measured by ellipsometry. The resulting thickness values are gathered in the graph in FIG. 6, and plotted as a function of the light radiation exposure dose at 172 nm and whether or not the film has been subjected to a post-exposure bake (PEB).

This graph thus allows to demonstrate that the PGFH copolymer can be crosslinked via exposure thereof to light radiation at 172 nm, and that if an area of the film is not exposed to radiation, it will be removed during the solvent rinse step. The example therefore shows that areas of the film can be specifically selected to undergo a crosslinking reaction. It should also be noted that the presence of a post-exposure bake makes it possible to retain a more considerable part of the initial film due to the diffusion of the photo-generated acid in the copolymer film, thus demonstrating the interest of this optional step in the method. It is also important to note that the wavelength at 172 nm is very close to the wavelength at 193 nm commonly used in optical lithography, therefore such a PGFH/TPST film will have a sensitivity equivalent, or even better at 193 nm, to that at the 248 nm wavelength also commonly used in optical lithography. Finally, it should be noted that the sensitivity of the material with respect to light radiation can be easily modified by playing on various parameters well known to the one skilled in the art, such as the ratio of constituents, the chemical nature of the sulfonium salt used as the PGA, etc.

Crosslinking by a Photochemical Process at λ=365 nm

The UV unit used was designed by the company EVG. It comprises a closed enclosure, irradiated by a UV lamp delivering a power of 3 W·cm² at the 365 nm wavelength located a few centimeters from the sample. The samples are first placed in the closed enclosure and the lamp is turned on for a defined time corresponding to a given light dose.

A 2 wt. % PGFH copolymer solution is made in absolute ethanol. A 4 wt. % solution of triarylsulfonium hexafluorophosphate (subsequently abbreviated “TAPS”) initially in a 50% solution in propylene carbonate (CAS: 109037-77-6) is prepared in methanol. A mixed solution of PGFH and TAPS is then prepared at 90 wt. % PGFH and 10 wt. % TAPS. The solution thus obtained is filtered on a PTFE filter with a porosity of 200 nm, and then dispensed by spin-coating at 2,000 revolutions per minute (rpm) on a silicon substrate with a side of 3 cm, so as to obtain a ˜60 nm thick, homogeneous film. A soft bake (“soft bake” in English) is then carried out at 60° C. for 1 minute to remove residual traces of solvent from the copolymer film, and the sample is then placed in the UV unit enclosure and subjected to a specific dose of light radiation. Subsequently, a post-exposure bake (PEB) is carried out at 90° C. for 2 minutes on a single hot plate to allow diffusion of the photo-generated acids into the copolymer film, and then the sample is rinsed in a bath of absolute ethanol for 2 minutes to remove non-crosslinked copolymer chains and the residual solvent is removed under nitrogen flow. The residual film thickness corresponding to the photo-crosslinked PGFH copolymer is measured by ellipsometry. The resulting thickness values are gathered in the graph in FIG. 7, and plotted as a function of the light radiation exposure dose at 365 nm.

This graph therefore demonstrates that PGFH copolymer can be crosslinked via exposure thereof to light radiation at 365 nm, and that if an area of the film is not exposed to radiation, it will be removed during the solvent rinse step. The example therefore shows that areas of the film can be specifically selected to undergo a crosslinking reaction. It should also be noted that the sensitivity of the material with respect to light radiation can be easily modified by playing on various parameters well known to the one skilled in the art, such as the ratio of constituents, the chemical nature of the sulfonium salt used as the PGA, etc.

### Example 5: Effect of Crosslinking on the Possible Dewettings of the Block Copolymer/Top Coat Stack

Homopolymers used as an underlayer are dissolved in a good solvent, such as 2 wt. % propylene glycol monomethyl ether acetate (PGMEA). The block copolymer No. 1 is dissolved in a good solvent such as 0.75 wt. % methyl isobutyl ketone (MIBK). The PGFH top coat copolymer is dissolved in 1.8 wt. % absolute ethanol to which 0.18% photoacid generator (TPST for a 172 nm and electron beam exposure, TAPS for a 365 nm exposure) is added. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The following procedure is carried out for samples corresponding to a given and predetermined experimental set:

“Solid/Liquid” Dewetting: (Dewetting of the Block Copolymer on its Neutral Underlayer: Reference No. 1

The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is subsequently dispensed by spin-coating at 2,000 revolutions per minute (rpm) to obtain a ˜25 nm thick, homogeneous film. The substrate is then annealed on a hot plate at 220° C. for 5 minutes. The sample is then subjected to a plasma of mild chemistry and conditions such as Ar (80 sccm), O₂ (40 sccm), 10 mT, 100 W_{source}, 10 W_{bias}, for 15 seconds in order to “freeze” the resulting structure and thus prevent polymer creep over time while improving SEM imaging conditions. The resulting sample is then characterized by scanning electron microscopy (SEM), by performing a statistic of ˜10 images at a typical magnification of ×5,000 or ×10,000 to determine the level of film dewetting. A typical SEM image corresponding to reference sample 1 is shown in FIG. 8, under letter a).

“Solid/Liquid/Liquid” Dewetting: (Dewetting of the Block Copolymer+Top Coat System, when the Top Coat is not Crosslinked): Reference No. 2

The PGFH top coat copolymer is first dissolved in 2 wt. % absolute ethanol, and then the resulting solution is filtered after the dissolution, and will be used as is afterwards. The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is then dispensed by spin-coating at 2,000 revolutions per minute (rpm) to obtain a ˜25 nm thick, homogeneous film. The top coat copolymer in ethanol is then dispensed onto the block copolymer film by spin-coating at 2,000 revolutions per minute (rpm) to obtain a ˜65 nm thick film. The substrate is then annealed on a hot plate at 220° C. for 5 minutes to organize the block copolymer. The samples are then subjected to a plasma of mild chemistry and conditions such as Ar (80 sccm), O₂ (40 sccm), 10 mT, 100 W_{source}, 10 W_{bias}, for 15 seconds in order to “freeze” the resulting structure and thus prevent polymer creep over time while improving SEM imaging conditions. The resulting sample is then characterized by scanning electron microscopy (SEM), by performing a statistic of ˜10 images at a typical magnification of ×5,000 or ×10,000 to determine the level of film dewetting. A typical SEM image corresponding to reference sample 2 is shown in FIG. 8, under letter b).

“Solid/Liquid/Solid” Dewetting: (Dewetting of the Block Copolymer+Top Coat System, when the Top Coat is Crosslinked): Approach Proposed by the Invention

The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is then dispensed by spin-coating at 2,000 revolutions per minute (rpm) to obtain a ˜25 nm thick, homogeneous film. The top coat copolymer, in a 90/10 blend with the PGA, in ethanol is then dispensed onto the block copolymer film by spin-coating at 2,000 revolutions per minute (rpm) so as to obtain a ˜65 nm thick film. The substrate is then subjected to a given stimulus (electron beam, light radiation) with a given dose (˜100 μC/cm² for exposure to an electron beam under conditions as exposed in Example 4; 15 to 30 mJ/cm² for exposure to light radiation with a wavelength of 172 nm under conditions as exposed in Example 4; 300 mJ/cm² for exposure to light radiation with a wavelength of 365 nm under conditions as exposed in Example 4). A post-exposure bake is then carried out at 90° C. for 2 or 3 minutes on a hot plate to allow the diffusion of the electro- or photo-generated acid into the top coat film. A second annealing at 220° C. for 5 minutes allows to organize the block copolymer. The samples are then subjected to a first plasma as described in Example 6 to remove the crosslinked top coat, followed by a second plasma of mild chemistry and conditions such as Ar (80 sccm), O₂ (40 sccm), 10 mT, 100 W_{source}, 10 W_{bias}, for 15 seconds to “freeze” the resulting structure of the block copolymer and thus prevent polymer creep over time while improving SEM imaging conditions. Each resulting sample is then characterized by scanning electron microscopy (SEM), by performing a statistic of ˜10 images at a typical magnification of ×5,000 or ×10,000 to determine the level of film dewetting. A typical SEM image corresponding to the samples, the top coat of which has been crosslinked according to an embodiment of the invention, is shown in FIG. 8, under letter c).

In images a) and b) of FIG. 8, the dark grey/black areas correspond to a cluster of copolymer film, so these are dewet areas, while the light grey areas correspond to the substrate exposed by the dewetting process. Image c) in FIG. 8 shows a continuous film of homogeneous thickness.

According to this example, it is obvious that if the top coat is not crosslinked (reference No. 2), it induces a deformation of the block copolymer layer leading quickly to a complete dewetting of the block copolymer on the neutralized surface. The block copolymer itself (reference No. 1) dewets onto the neutralization layer corresponding to the self-organization temperature of the block copolymer, when no top coat is present. Finally, neither the block copolymer film nor the top coat film was found to dewet when the top coat underwent a crosslinking step, either by exposure to an electron beam or by exposure to light radiation, before being subjected to the self-organization temperature of the block copolymer (“solid/liquid/solid dewetting”). It is therefore undeniable that the crosslinked top coat allows to effectively control, or even eliminate, the possible dewetting phenomena of the stack. In addition, it can be noted that this last configuration allows to obtain perpendicularly oriented patterns, as described in Example 7.

### Example 6: Plasma Etching/Removal of the Top Coat Layer

The top coat film removal/dry etching experiments were conducted in an inductively coupled plasma DPS reactor, from Applied Materials, the wall of which are made of aluminum. The samples are physically bonded to a 200 mm diameter silicon wafer before being introduced into the reactor chamber. The plasma is inductively excited via two 13.56 MHz radio frequency antennas with up to 3 kW power supply to improve the uniformity of the ion flow.

Plasma with a chemistry and conditions such as CF₄ (50 sccm), O₂ (70 sccm), 10 mT, 100 W_{source}, 10 W_{bias}, is carried out on PGFH copolymer films of an initial thickness of ˜130 nm with variable plasma times. The PGFH films are prepared as described in Example 4. The concentration of the constituents is adjusted here to 4 wt. % in order to obtain slightly thicker films than in Example 4 and thus have a better accuracy on the etching speed of the PGFH film; the rest of the method is unchanged. Once the plasma has been applied, the residual film thicknesses are measured by ellipsometry. The results are shown in Table 2 below and illustrated in the graph in FIG. 9.

TABLE 2
residual thickness measured for a PGFH film having
undergone different plasma times. According to this
example, the PGFH copolymer is then etched at a speed
of ~4.8 nm · s⁻¹ under these plasma conditions.

| Duration (sec) | Residual thickness (nm) |
|---|---|
| 7 | 95 |
| 10 | 79 |
| 13 | 64 |
| 16 | 52 |
| 20 | 32 |

According to the samples prepared as in Example 7 below, as well as the data shown above, the top coat with an initial thickness of ˜60 nm is therefore removed entirely with a plasma time of 13 seconds. Thereafter, optionally, a plasma with mild chemistry and conditions of Ar (80 sccm), O₂ (40 sccm), 10 mT, 200 W_{source}, 20 W_{bias}, carried out for 10 seconds, allows partial removal of the phase corresponding to the PS of the block copolymer in order to improve the contrast in SEM imaging.

It should be noted that in this example, the plasma chemistries and conditions under which the PGFH film can be removed are very arbitrary, and therefore other equivalent conditions easily established by the one skilled in the art would equally well achieve the same result.

### Example 7: Self-Organization of Block Copolymer According to the Invention—Crosslinked Neutral Top Coat

Homopolymers used as an underlayer are dissolved in a good solvent, such as 2 wt. % propylene glycol monomethyl ether acetate (PGMEA). The block copolymer is dissolved in a good solvent such as 0.75 wt. % methyl isobutyl ketone (MIBK). The PGFH top coat copolymer is dissolved in 1.8 wt. % absolute ethanol to which 0.18% photoacid generator (TPST for a 172 nm and electron beam exposure, TAPS for a 365 nm exposure) is added. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is subsequently dispensed by spin-coating at 2,000 revolutions per minute (rpm) to obtain a ˜25 nm thick, homogeneous film. The solution of top coat copolymer/PGA in ethanol is then dispensed onto the block copolymer film by spin-coating at 2,000 revolutions per minute (rpm) to obtain a ˜65 nm thick film. The substrate is then subjected to a given stimulus (electron beam, light radiation) with a given dose (˜100 μC/cm² for exposure to an electron beam under conditions as exposed in Example 4; 15 to 30 mJ/cm² for exposure to light radiation with a wavelength of 172 nm under conditions as exposed in Example 4; 300 mJ/cm² for exposure to light radiation with a wavelength of 365 nm under conditions as exposed in Example 4). A post-exposure bake is then carried out at 90° C. for 2 or 3 minutes on a hot plate to allow the diffusion of the electro- or photo-generated acid into the top coat film. The samples are then subjected to a first plasma as described in Example 6 to remove the crosslinked top coat, followed by a second plasma of mild chemistry and conditions such as Ar (80 sccm), O₂ (40 sccm), 10 mT, 100 W_{source}, 10 W_{bias}, for 15 seconds to “freeze” the resulting structure of the block copolymer and thus prevent polymer creep over time while improving SEM imaging conditions. The various samples are then analyzed by scanning electron microscopy (SEM) on a CD-SEM H9300 from Hitachi. The results obtained are shown in FIG. 10, which represents the SEM image of a sample of block copolymer No. 1, the self-organization of which is perpendicular to the substrate and the period of which is of the order of 18 nm, for the various exposure stimuli. It is noted that the same type of results (PDMSB-b-PS lamellar block copolymer film with patterns oriented entirely perpendicular to the substrate) is observed for smaller thicknesses (0.5 to 1 times the period of the block copolymer used), or thicknesses larger than that reported (more than 4 times the period of the block copolymer used).

According to this example, it can be seen that the domains of the lamellar PDMSB-b-PS block copolymer are indeed oriented perpendicular to the substrate for the different top coat compositions studied. However, when a copolymer not containing trifluoroethyl methacrylate (e.g.: 25/0/75) is used as a top coat under the same conditions, a mixed parallel/perpendicular or fully parallel orientation of the patterns is obtained, thus demonstrating the value of the presence of trifluoroethyl methacrylate as a co-monomer in the architecture of the top coat for controlling the perpendicular orientation of the patterns of the block copolymer. Finally, as in Example 5 above (see FIG. 8 c)), under these method conditions (especially the self-organizing annealing), no dewetting is observed on the films corresponding to FIG. 10.

### Example 8: Electron Beam and UV Patterning

Electron Beam Patterning

The equipment used for electron beam (“e-beam” in English) lithography is a JEOL 6300FS instrument operating at 100 kV, the electron beam intensity of which is set at 5 nA; an exposure dose of 150 μC/cm² is arbitrarily selected for proof of concept.

A 2 wt. % PGFH copolymer solution is made in absolute ethanol. A 2 wt. % solution of TPST is prepared, also in absolute ethanol. A mixed solution of PGFH and TPST is then prepared at 90 wt. % PGFH and 10 wt. % TPST. The solution thus obtained is filtered on a PTFE filter with a porosity of 200 nm, and then dispensed by spin-coating at 2,000 revolutions per minute (rpm) on a silicon substrate with a side of 3 cm, so as to obtain a ˜60 nm thick, homogeneous film. A soft bake (soft bake) is then carried out at 60° C. for 1 minute to remove residual traces of solvent from the copolymer film, and then the sample is exposed to an electron beam at a dose of 150 μC/cm² to draw arrays of lines 100 μm long by 1 μm wide, 10 μm apart. After exposure, a bake (“post-exposure bake” in English, or PEB) is carried out at 90° C. for 2 minutes to allow the diffusion of the electro-generated acid into the PGFH film. The sample is then rinsed in a bath of absolute ethanol for 1 minute to remove unexposed areas from the substrate, and then the residual solvent is removed under nitrogen flow. The sample thus prepared is then observed under an optical microscope and by SEM to characterize the patterns drawn. The characterizations are shown in FIG. 11, which represents under letter a) an image taken by light microscopy and under letter b) an image taken by scanning electron microscopy. In these figures, the grey/black areas that stand out from the background correspond to the patterns drawn via crosslinking of the PGFH copolymer.

The example therefore demonstrates that PGFH copolymer, which will also serve as a top coat in directed block copolymer assembly, can be used as an electron beam lithography resin to draw nanosized patterns of interest.

Patterning by Exposure to Light Radiation (λ=365 nm)

The UV unit used is a mask aligner of the MJB4 type developed by the company Suss MicroTec. It includes a UV lamp delivering a power of ˜12 W·cm² at the 365 nm wavelength located a few centimeters above the sample. The sample is first placed on the dedicated sample holder, and then the lithography mask is placed on the sample by contact, and the lamp is turned on for a defined time corresponding to a given light dose of ˜300 mJ/cm².

A 2 wt. % PGFH copolymer solution is made in absolute ethanol. A 4 wt. % solution of “TAPS” PGA initially in a 50% solution in propylene carbonate is prepared in methanol. A mixed solution of PGFH and TAPS is then prepared at 90 wt. % PGFH and 10 wt. % TAPS. The solution thus obtained is filtered on a PTFE filter with a porosity of 200 nm, and then dispensed by spin-coating at 2,000 revolutions per minute (rpm) on a silicon substrate with a side of 3 cm, so as to obtain a ˜60 nm thick, homogeneous film. A soft bake (“soft bake”) is then carried out at 60° C. for 1 minute to remove residual traces of solvent from the copolymer film, and then the sample is placed on the sample holder of the mask aligner and then subjected to a specific dose of light radiation through the lithography mask (e.g. arbitrary line-like patterns of varying dimensions up to 1 μm in width). Subsequently, a PEB annealing is carried out at 90° C. for 2 minutes on a single hot plate to allow diffusion of the photo-generated acids into the copolymer film, and then the sample is rinsed in a bath of absolute ethanol for 2 minutes to remove non-crosslinked copolymer chains and the residual solvent is removed under nitrogen flow. The sample thus prepared is then observed under an optical microscope and by SEM to characterize the patterns drawn. The characterizations are shown in FIG. 12 which represents under letter a) an image taken by light microscopy and under letter b) an image taken by scanning electron microscopy. In these figures, the grey/black areas that stand out from the background correspond to the patterns drawn via crosslinking of the PGFH copolymer.

The example therefore demonstrates that PGFH copolymer, which will also serve as a top coat in directed block copolymer assembly, can be used as a resin for optical lithography via UV radiation to draw nanosized patterns of interest.

### Example 9: Neutrality of Patterns (or Patterns) and Selection of Perpendicular/Parallel Areas

Electron Beam Exposure:

The equipment used for electron beam (“e-beam”) lithography is a JEOL 6300FS instrument operating at 100 kV, the electron beam intensity of which is set at 5 nA; an exposure dose of 150 μC/cm² is arbitrarily selected for proof of concept.

Homopolymers used as an underlayer are dissolved in a good solvent, such as 2 wt. % propylene glycol monomethyl ether acetate (PGMEA). The block copolymer No. 1 is dissolved in a good solvent such as 0.75 wt. % methyl isobutyl ketone (MIBK). The PGFH top coat copolymer is dissolved in 1.8 wt. % absolute ethanol to which 0.18% photoacid generator (TPST) is added. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is subsequently dispensed by spin-coating at 2,000 revolutions per minute (rpm) to obtain a ˜25 nm thick, homogeneous film. The top coat copolymer in ethanol is then dispensed onto the block copolymer film by spin-coating at 2,000 revolutions per minute (rpm) to obtain a ˜65 nm thick film. The substrate is then subjected to an electron beam with a dose of ˜150 μC/cm², in order to draw 100 μm×100 μm wide patterns, thus defining neutral exposed areas for the block copolymer and unexposed [to the electron beam] areas on the substrate. A post-exposure bake is then carried out at 90° C. for 2 or 3 minutes on a hot plate to allow the diffusion of the electro-generated acid in the top coat film on the areas exposed to the electron beam. The sample is then rinsed in a bath of absolute ethanol, and then the solvent is dried under nitrogen flow. Subsequently, a 1% PGFH non-neutral top coat copolymer (composition 25/0/75) in ethanol, to which 0.1% TPST is added, is dispensed at 2,000 revolutions per minute (rpm) onto the pre-patterned substrate. The sample is then subjected to light radiation at 172 nm for a dose of 30 mJ/cm² in order to crosslink this second top coat, and then a post-exposure bake (PEB) is carried out at 90° C. for 2 minutes in order to diffuse the photo-generated acid into the second top coat. Annealing at 220° C. for 5 minutes allows to organize the block copolymer. The sample is then subjected to a first plasma as described in Example 6 to remove the crosslinked top coat, followed by a second plasma of mild chemistry and conditions such as Ar (80 sccm), O₂ (40 sccm), 10 mT, 100 W_{source}, 10 W_{bias}, for 15 seconds to “freeze” the resulting structure of the block copolymer, and thus prevent polymer creep over time while improving the SEM imaging conditions. The sample is characterized on a CDSEM H9300 from Hitachi. The result of the characterization is shown in FIG. 13 which represents the SEM images of the areas exposed and unexposed to the electron beam. The area initially exposed to the electron beam has lamellar block copolymer patterns perpendicular to the substrate, while the unexposed area has patterns parallel to the substrate.

The example therefore demonstrates that neutral areas (perpendicular block copolymer patterns) for the block copolymer and non-neutral areas (parallel block copolymer patterns) can be defined on the substrate by lithography of the PGFH copolymer via exposition thereof to an electron beam.

Exposure by Light Radiation at λ=365 nm

The UV unit used is a mask aligner of the MJB4 type developed by the company Suss MicroTec. It includes a UV lamp delivering a power of ˜12 W·cm⁻² at the 365 nm wavelength located a few centimeters above the sample. The sample is first placed on the dedicated sample holder, and then the lithography mask is placed on the sample by contact, and the lamp is turned on for a defined time corresponding to a given light dose of ˜300 mJ/cm².

Homopolymers used as an underlayer are dissolved in a good solvent, such as 2 wt. % propylene glycol monomethyl ether acetate (PGMEA). The block copolymer No. 1 is dissolved in a good solvent such as 0.75 wt. % methyl isobutyl ketone (MIBK). The top coat copolymer PGFH is dissolved in 2 wt. % absolute ethanol. The PGA “TAPS” is prepared by dissolving an initial 50% solution in propylene carbonate at 4% in methanol. A mixed solution of PGFH and TAPS is then prepared at 90 wt. % PGFH and 10 wt. % TAPS. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The neutral underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is then dispensed by spin-coating at 2,000 revolutions per minute (rpm) to obtain a ˜25 nm thick, homogeneous film. The top coat copolymer in ethanol is then dispensed onto the BCP film by spin-coating at 2,000 revolutions per minute (rpm) to obtain a ˜65 nm thick film. The substrate is placed on the sample holder of the UV unit, and then subjected to UV radiation through the selected lithography mask to draw any patterns (e.g. lines of varying dimensions), thus defining exposed areas neutral for the block copolymer and unexposed [to UV radiation] areas on the substrate. A post-exposure bake is then carried out at 90° C. for 2 or 3 minutes on a hot plate to allow the diffusion of the photo-generated acid in the top coat film on the areas exposed to light radiation. The sample is then rinsed in a bath of absolute ethanol to dissolve the areas not exposed to radiation, and then the solvent is dried under nitrogen flow. Subsequently, a 1% PGFH non-neutral top coat copolymer (composition 25/0/75) in ethanol, to which 0.1% TPST is added, is dispensed at 2,000 revolutions per minute (rpm) onto the pre-patterned substrate. The sample is then subjected to light radiation at 172 nm for a dose of 30 mJ/cm² in order to crosslink this second top coat, and then a post-exposure bake (PEB) is carried out at 90° C. for 2 minutes in order to diffuse the photo-generated acid into the second top coat. Annealing at 220° C. for 5 minutes allows to organize the block copolymer. The sample is then subjected to a first plasma as described in Example 6 to remove the crosslinked top coat, followed by a second plasma of mild chemistry and conditions such as Ar (80 sccm), O₂ (40 sccm), 10 mT, 100 W_{source}, 10 W_{bias}, for 15 seconds to “freeze” the resulting structure of the block copolymer, and thus prevent polymer creep over time while improving the SEM imaging conditions. The sample is characterized on a CDSEM H9300 from Hitachi. The result of the characterization is shown in FIG. 14 which shows the SEM images of the areas exposed and unexposed to radiation at 365 nm. The area initially exposed to radiation at 365 nm has lamellar block copolymer patterns perpendicular to the substrate, while the unexposed area has patterns parallel to the substrate.

The example therefore demonstrates that neutral areas (perpendicular BCP patterns) for the BCP and non-neutral areas (parallel BCP patterns) can be defined on the substrate by lithography of the appropriately composed PGFH copolymer via exposition thereof to UV radiation.

### Example 10: Planarity of Interfaces

Homopolymers used as an underlayer are dissolved in a good solvent, such as 2 wt. % propylene glycol monomethyl ether acetate (PGMEA). The block copolymer No. 2 is dissolved in a good solvent such as 3 wt. % methyl isobutyl ketone (MIBK). The top coat copolymer PGFH is dissolved in 2 wt. % absolute ethanol. The PGA “TAPS” is prepared by dissolving an initial 50% solution in propylene carbonate at 4% in methanol. A mixed solution of PGFH and TAPS is then prepared at 90 wt. % PGFH and 10 wt. % TAPS. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer solution is then dispensed by spin-coating at 1000 revolutions per minute (rpm) to obtain a ˜130 nm thick, homogeneous film. Optionally, annealing on a hot plate at 90° C. for 30 seconds is carried out to evaporate the residual solvent. The top coat solution is then dispensed onto the block copolymer layer by spin-coating at 2,000 revolutions per minute (rpm) so as to obtain a top coat thickness of −60 nm. The film stack is then exposed to light radiation with a wavelength of 365 nm at a dose of ˜300 mJ/cm², and then a post-exposure bake (PEB) at 90° C. for 3 minutes is performed to promote the diffusion of the photo-generated acid into the top coat film. The block copolymer is then self-organized at a temperature of 220° C. for 10 minutes.

For the analysis of the sectioned sample via FIB-STEM (fast ion bombardment-scanning transmission electronic microscope) preparation, the following procedure is used: the preparation of the thin slide of the sample as well as its STEM analysis are carried out on a Helios 450S instrument. A 100 nm platinum layer is first deposited on the sample by evaporation to prevent polymer damage. An additional 1 μm layer is deposited on the sample in the STEM enclosure by a high-energy ion beam. After careful alignment perpendicularly to the sample (sectional view), a thin slide thereof is extracted via FIB, and then gradually refined until a width of approximately 100 nm is obtained. An in-situ observation is then carried out using the STEM detector. The result of the analysis is shown in FIG. 15 which represents the assembly of the lamellar block copolymer (BCP) No. 2, as seen in cross section by FIB-STEM preparation. Microscopy indicates that the lamellae are perpendicular to the substrate over the entire thickness of the film (in grey/black: PDMSB lamellae; in grey/white: PS lamellae).

FIG. 15 shows that the crosslinking of the top coat material makes it possible to maintain a particularly clear interface between the top coat material and the block copolymer, as proposed in the context of the invention (no observable mixing between the two materials), as well as a nicely flat film for the two materials. Incidentally, FIG. 15 also shows that the invention is particularly effective both in generating patterns (lamellae) perfectly oriented in the same direction throughout the thickness of the block copolymer film, as well as in generating block copolymer patterns having a high aspect ratio (˜7 nm wide by ˜25 nm thick lamella, i.e. an aspect ratio of ˜18).

### Example 11: Stacking of Block Copolymer Films

Homopolymers used as an underlayer are dissolved in a good solvent, such as 2 wt. % propylene glycol monomethyl ether acetate (PGMEA). The block copolymer No. 1 and the block copolymer No. 3 are dissolved in a good solvent such as methyl isobutyl ketone (MIBK), each at 0.75 wt. %. The top coat copolymer PGFH is dissolved in 2 wt. % absolute ethanol. The PGA “TAPS” is prepared by dissolving an initial 50% solution in propylene carbonate at 4% in methanol. A mixed solution of PGFH and TAPS is then prepared at 90 wt. % PGFH and 10 wt. % TAPS. Each solution is filtered on PTFE filters with a porosity of 200 nm to remove potential particles and dust. The silicon substrates are cut into 3 cm×3 cm samples from 200 mm wafers of silicon with a [100] crystallographic orientation, and then used as is.

The underlayer solution is dispensed by spin-coating onto the silicon substrate at a speed of 700 revolutions per minute (rpm), to obtain a ˜70 nm thick film. The substrate is then annealed at 200° C. for 75 seconds in order to graft the molecules onto said substrate, and then the excess ungrafted material is simply rinsed off in a solvent bath (PGMEA), and the residual solvent is blown off under a nitrogen flow. The block copolymer No. 3 solution is then dispensed by spin-coating at 2,000 revolutions per minute (rpm) to obtain a ˜27 nm thick, homogeneous film. Optionally, annealing on a hot plate at 90° C. for 30 seconds is carried out to evaporate the residual solvent. The top coat solution is then dispensed onto the block copolymer layer by spin-coating at 2,000 revolutions per minute (rpm) so as to obtain a ˜60 nm thick top coat. The film stack is then exposed to light radiation with a wavelength of 365 nm at a dose of ˜300 mJ/cm², and then a post-exposure bake (PEB) at 90° C. for 3 minutes is performed to promote diffusion of the photo-generated acid into the top coat film. The underlayer solution is dispensed by spin-coating on the film stack at a speed of 700 revolutions per minute (rpm), to obtain a ˜70 nm thick film. The substrate is then annealed at 200° C. for 75 seconds to graft the underlayer onto the first top coat film, and then the excess ungrafted material is simply rinsed off by pure MIBK spin-coating until evaporation. The block copolymer No. 1 solution is then dispensed by spin-coating at 2,000 revolutions per minute (rpm) to obtain a ˜27 nm thick, homogeneous film. Optionally, annealing on a hot plate at 90° C. for 30 seconds is carried out to evaporate the residual solvent. The top coat solution is then dispensed onto the block copolymer layer by spin-coating at 2,000 revolutions per minute (rpm) so as to obtain a ˜60 nm thick top coat. The film stack is then exposed to light radiation with a wavelength of 365 nm at a dose of ˜300 mJ/cm², and then a PEB annealing for 3 minutes at 90° C. is carried out to promote diffusion of the photo-generated acid into the top coat film. The stack of different films is then annealed at a temperature of 220° C. for 5 minutes to promote the self-organization of the different BCP block copolymers (BCP No. 1 and BCP No. 3) in the stack.

For the analysis of the sectioned sample via FIB-STEM (fast ion bombardment-scanning transmission electronic microscope) preparation, the following procedure is used: the preparation of the thin slide of the sample as well as its STEM analysis are carried out on a Helios 450S instrument. A 100 nm platinum layer is first deposited on the sample by evaporation to prevent polymer damage. An additional 1 μm layer is deposited on the sample in the STEM enclosure by a high-energy ion beam. After careful alignment perpendicularly to the sample (sectional view), a thin slide thereof is extracted via FIB, and then gradually refined until a width of approximately 100 nm is obtained. An in-situ observation is then carried out using the STEM detector. The result of the analysis is shown in FIG. 16 which represents the stack of the different films as seen in cross section by FIB-STEM.

FIG. 16 shows successive films of block copolymers (BCP) of different periods (˜24 nm for BCP No. 3, ˜18 nm for BCP No. 1), each self-organized perpendicularly to the substrate, without observing miscibility between the different films present. The example thus demonstrates that the invention makes it possible to stack block copolymer films at will thanks to the crosslinking of the top coat films, without the stack dewetting from the substrate.

1. A method for manufacturing a flat polymeric stack, said method consisting in depositing on a substrate a first layer of non-crosslinked (co)polymer, and then a second layer of (co)polymer, at least one of the (co)polymer layers initially being in a liquid or viscous state, wherein, at the time of the deposition of the second layer on the first layer, the second layer is in the form of a prepolymer composition (pre-TC) comprising one or more monomer(s) and/or dimer(s) and/or oligomer(s) and/or polymer(s) in solution, and wherein an additional step consists in submitting said second layer to a stimulus selected from plasma, ion bombardment, electrochemical process, chemical species and light radiation capable of causing a crosslinking reaction of molecular chains within said prepolymer composition of said second layer and allowing the production of a crosslinked top coat (TC) layer.

2. The method according to claim 1, wherein the prepolymer composition (pre-TC) comprises a solvent, said solvent being selected to be entirely “orthogonal” to a polymeric system of the first layer.

3-6: (canceled)

7. The method according to one of claim 1, wherein at least one chemical entity of the prepolymer composition has at least one fluorine and/or silicon and/or germanium atom, and/or an aliphatic carbon-based chain of at least two carbon atoms in its chemical formula.

8. The method according to claim 1, wherein said prepolymer composition (pre-TC) also comprises in its formulation:
a chemical entity selected from an antioxidant, a weak acid or base, able to trap said chemical entity capable of initiating the crosslinking reaction, and/or
one or more additives for improving wetting and/or adhesion, and/or uniformity of the second layer deposited on the first layer, and/or
one or more additives for absorbing one or more ranges of light radiations of different wavelengths, or for modifying the electrical conductivity properties of the prepolymer (pre-TC).

9. The method according to one claim 1, wherein the (co)polymer layer comprises a block copolymer (BCP) and the top coat layer has a neutral surface energy with respect to blocks of the block copolymer wherein.

10. The method according to claim 1, wherein the second layer comprises constituent monomer(s) and/or dimer(s) and/or oligomer(s) and/or polymer(s) selected from acrylate or diacrylate or triacrylate or multi-acrylate, methacrylate, or multi-methacrylate, or polyglycidyl or vinyl, fluoroacrylate or fluoromethacrylate, vinyl fluoride or fluorostyrene, alkyl acrylate or methacrylate, hydroxyalkyl acrylate or methacrylate, alkylsilyl acrylate or methacrylate derivatives, unsaturated esters/acids such as fumaric or maleic acids, vinyl carbamates and carbonates, allyl ethers, and thiol-ene systems.

11-19: (canceled)

20. The method according to claim 1, wherein the first layer is a block copolymer (BCP) capable of nanostructuring at an assembly temperature, and wherein prior to the step of depositing the first layer of block copolymer, the method comprises a step of neutralizing a surface of the underlying substrate, and wherein, after the step of crosslinking the second layer to form a crosslinked top coat layer (TC), the method comprises a step of nanostructuring the block copolymer constituting the first layer by subjecting the stack obtained to an assembly temperature, said assembly temperature being lower than a temperature at which the top coat (TC) material behaves like a viscoelastic fluid, said temperature being higher than the glass transition temperature of said top coat material and, said assembly temperature being lower than the glass transition temperature of the top coat (TC) layer in its crosslinked form.

21. The method according to claim 20, wherein the step of neutralizing the surface of the underlying substrate consists in predrawing patterns on the surface of the substrate, said patterns being predrawn by a lithography step or a sequence of lithography steps of any nature prior to the step of depositing the first layer of block copolymer (BCP), said patterns being intended to guide the organization of said block copolymer (BCP) by a technique known as chemical epitaxy or graphoepitaxy, or a combination of these two techniques, in order to obtain a neutralized or pseudo-neutralized surface.

22. (canceled)

23. The method according to claim 20, wherein the first block copolymer (BCP) layer is deposited to a thickness at least equal to 1.5 times a minimum thickness of the block copolymer.

24. The method according to one of claim 2, wherein the solvent of the second layer is selected from solvents or solvent mixtures, the Hansen solubility parameters of which are such that δₚ≥10 MPa^{1/2} and/or δₕ≥10 MPa^{1/2}, and with δ_{d}<25 MPa^{1/2}.

25. The method according to claim 24, wherein the solvent of the second layer is selected from alcohols such as methanol, ethanol, isopropanol, 1-methoxy-2-propanol, ethyl lactate, diols such as ethylene glycol or propylene glycol, or from dimethyl sulfoxide (DMSO), dimethylformamide, dimethylacetamide, acetonitrile, gammabutyrolactone, water, or a mixture thereof.

26. The method according to claim 1, wherein the second layer comprises a multi-component mixture of monomers and/or dimers and/or oligomers and/or polymers each bearing functions ensuring crosslinking, and also different monomer units, the surface energies of which vary from one monomer unit to another.

27. The method according to claim 1, wherein the second layer also comprises plasticizers and/or wetting agents, added as additives.

28. The method according to claim 1, wherein the second layer also comprises rigid comonomers selected from derivatives including either one or more aromatic ring(s) in their structure, or monocyclic or polycyclic aliphatic structures, and having one or more chemical function(s) adapted to the crosslinking reaction targeted; and more particularly derivatives of norbornene, isobornyl acrylate or methacrylate, styrene, anthracene, adamantyl acrylate or methacrylate.

29. A method for manufacturing a nanolithography mask by directed assembly of block copolymers, said method comprising the method according to claim 9, wherein after the step of nanostructuring the block copolymer constituting the first layer, an additional step consists in removing the top coat layer (TC) in order to leave a film of nanostructured block copolymer of a minimum thickness, and then at least one of the blocks of said block copolymer, oriented perpendicular to the interfaces, is removed in order to form a porous film suitable for use as a nanolithography mask.

30. The method for manufacturing a nanolithography mask according to claim 29, wherein when the block copolymer is deposited to a thickness greater than the minimum thickness, an overthickness of said block copolymer is removed simultaneously with or successively to the removal of the top coat layer, so as to leave a film of nanostructured block copolymer of a minimum thickness, and then at least one of the blocks of said block copolymer, oriented perpendicular to the interfaces, is removed so as to form a porous film suitable for use as a nanolithography mask.

31. (canceled)

32. (canceled)

33. The method for manufacturing a nanolithography mask according to claim 29, wherein, at the time of the step of crosslinking the top coat layer, the stack is subjected to light radiation and/or an electron beam localized on some areas of the top coat layer, so as to create crosslinked top coat (TC) areas having a neutral affinity with respect to the underlying block copolymer and non-crosslinked areas (pre-TC) having a non-neutral affinity with respect to the underlying block copolymer, and wherein after localized photo-crosslinking of the top coat layer, the stack is rinsed with the solvent which allowed the deposition of the prepolymer layer (pre-TC) so as to remove the non-irradiated areas, and another prepolymer material, which is not neutral with respect to the underlying block copolymer, is deposited in the areas which have not been irradiated beforehand and which are free of the top coat layer, and then said non-neutral prepolymer material is exposed to a stimulus so as to crosslink it at the predefined places.

34. (canceled)

35. (canceled)

36. The method for manufacturing a nanolithography mask according to claim 29, wherein at the time of annealing the stack at the assembly temperature of the block copolymer (BCP), nanodomains (20, 21; 41, 42) are formed perpendicular to the interfaces in areas facing the areas of the neutral crosslinked top coat layer (TC), and nanodomains are formed parallel to the interfaces in areas of the block copolymer facing the areas free of a crosslinked neutral top coat layer.

37. A polymeric stack comprising at least two (co)polymer layers stacked one on the other, wherein a top coat (TC) is deposited on a first (co)polymer layer by in situ crosslinking in accordance with the method according to claim 1, said stack being intended to be used in applications selected from surface protection for the aerospace or aeronautical or motor vehicle or wind turbine sectors, paints, inks, the manufacture of membranes, the production of microelectronic, optoelectronic, or microfluidic components.

38. The method according to claim 1, wherein the first layer comprises a block copolymer (BCP) able to nanostructure at an assembly temperature, the assembly temperature of the block copolymer being lower than a temperature at which the top coat TC in its crosslinked form behaves as a viscoelastic fluid, preferably lower than the glass transition temperature of the top coat TC layer in its crosslinked form.
